(19) United States
(12) Patent Application Publication
(10) Pub. No.: US 2018/0054170 A1
(43) Pub. Date: Feb. 22, 2018

(54) DISTORTION COMPENSATION DEVICE AND COEFFICIENT UPDATE METHOD

(71) Applicant: FUJITSU LIMITED, Kawasaki-shi (JP)

(72) Inventors: Hiroaki Arai, Kawasaki (JP); HIROYOSHI ISHIKAWA, Kawasaki (JP); Kazuo Nagatani, Yokohama (JP)

(73) Assignee: FUJITSU LIMITED, Kawasaki-shi (JP)

(21) Appl. No.: 15/676,211

(22) Filed: Aug. 14, 2017

(30) Foreign Application Priority Data
Aug. 19, 2016 (JP) 2016-161554
May 30, 2017 (JP) 2017-107127

(51) Int. Cl. H03F 1/32; H03F 3/24; H04L 27/36; H04B 1/04; H04L 25/03; H04L 27/26

(52) U.S. Cl. CPC H03F 1/3247; H03F 3/24; H04L 27/368; H04B 1/0475; H04B 2001/0433; H04L 27/2614; H03F 2201/3224; H03F 2201/3233; H04B 2001/0425; H04L 25/03343

(57) ABSTRACT

A distortion compensation device includes a distortion compensation unit, a feedback coefficient calculating unit, a clip processing unit, and an updating unit. The distortion compensation unit generates a distortion compensation signal from a transmission signal by using a distortion compensation coefficient and inputs the generated distortion compensation signal to a power amplifier. The feedback coefficient calculating unit calculates a feedback coefficient based on an output signal from the power amplifier. The clip processing unit outputs the feedback coefficient when absolute value of the feedback coefficient is less than a threshold. Furthermore, the clip processing unit outputs a feedback coefficient of which absolute value is less than the threshold when the absolute value of the feedback coefficient is greater than the threshold. The updating unit updates the distortion compensation coefficient by using an error between the transmission signal and the output signal, a predetermined step coefficient, and the feedback coefficient.

### CROSS-REFERENCE TO RELATED APPLICATIONS

This application is based upon and claims the benefit of priority of the prior Japanese Patent Application No. 2018-161554, filed on Aug. 19, 2016 and Japanese Patent Application No. 2017-107127, filed on May 30, 2017, the entire contents of which are incorporated herein by reference.

### FIELD

The embodiments discussed herein are related to a distortion compensation device and a coefficient update method.

### BACKGROUND

In a radio transmission device, a power amplifier that amplifies power of a transmission signal is provided. In the radio transmission device, in general, in order to increase the power efficiency of the power amplifier, the power amplifier is operated in the vicinity of the saturation region of the power amplifier. However, when the power amplifier is operated in the vicinity of the saturation region, nonlinear distortion in the power amplifier is increased. If the nonlinear distortion is increased, the signal quality, such as the ratio of power leakage into an adjacent channel (adjacent channel leakage ratio: hereinafter, referred to as ACLR), or the like, is degraded. Thus, in order to reduce this nonlinear distortion, in the radio transmission device, a distortion compensation device that compensates nonlinear distortion is provided.

There is a “digital predistortian scheme” as one of the distortion compensation schemes used in a distortion compensation device. In a distortion compensation device that uses the digital predistortion scheme, a distortion compensation coefficient that has the inverse characteristic of the nonlinear distortion in the power amplifier is previously multiplied by the transmission signal and then a transmission signal in which the distortion compensation coefficient has been multiplied is input to the power amplifier. Consequently, the nonlinear distortion in the output signal that is output from the power amplifier is canceled out. The distortion compensation coefficients are stored in a look up table (LUT) by being associated with the addresses calculated from the transmission signal.

Furthermore, it is known that the phenomenon called memory effect occurs in the power amplifier with high power efficiency. The memory effect is a phenomenon in which an output with respect to an input to the power amplifier at a certain time point is affected by an input that is received at a time point in a past. To reduce the memory effect, distortion compensation is performed by also using a transmission signal that is present before by a predetermined number of samples. The distortion compensation, coefficients in the LUT are sequentially updated such that a difference between the signal that is obtained by feeding back the output signal sent from the power amplifier and the transmission signal that has not been subjected to the distortion compensation becomes small. As an update method of the distortion compensation coefficients, a method of, for example, normalized least-mean-square (NLMS), or the like, is known.

However, in the signal that is fed back from the power amplifier, a noise component, such as thermal noise of, for example, an analog-to-digital converter (ADC), or the like, is included. Thus, if the power of the fed back signal is small, a signal to noise ratio (hereinafter, referred to as an SN ratio) becomes small and the influence of the noise component becomes large. Thus, if the fed back signal is small, the value of an update amount of the distortion compensation coefficients calculated based on the fed back signal may sometimes be greatly different from a desired value.

To avoid this problem, there is a known technology in which, if the value of the address calculated from the transmission signal that has not been subjected to the distortion compensation is less than a threshold, the distortion compensation coefficient associated with the address having a value less than the threshold is not used by clipping the address by using the threshold. Prior art examples are disclosed in International Publication Pamphlet No. WO 2003/103163 and International Publication Pamphlet No. WO 2003/103167.

The quality of the signal, such as ACLR, or the like, in a case where the amplitude of the transmission signal is small is improved to some extent by clipping the address associated with the transmission signal that has not been subjected to the distortion compensation by using a predetermined threshold; however, the quality of the signal is still low. Consequently, the quality of the signal needs to be further improved.

### SUMMARY

According to an aspect of an embodiment, a distortion compensation device compensates distortion generated in a power amplifier. The distortion compensation device includes a distortion compensation unit, a calculating unit, a clip processing unit, and an updating unit. The distortion compensation unit generates a distortion compensation signal by performing a predetermined arithmetic operation on a transmission signal by using a distortion compensation coefficient and that inputs the generated distortion compensation signal to the power amplifier. The calculating unit calculates a feedback coefficient based on an output signal output from the power amplifier. The clip processing unit outputs, when absolute value of the feedback coefficient calculated by the calculating unit is equal to or less than a threshold, the feedback coefficient calculated by the calculating unit and that outputs, when the absolute value of the feedback coefficient calculated by the calculating unit is greater than the threshold, the feedback coefficient of which absolute value is equal to or less than the threshold. The updating unit updates the distortion compensation coefficient by using an error between the transmission signal and the output signal, a predetermined step coefficient, and the feedback coefficient output from the clip processing unit.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram illustrating an example of a distortion compensation device according to a first embodiment;

FIG. 2 is a schematic diagram illustrating an example of a threshold according to the first embodiment;

FIG. 3 is a schematic diagram illustrating the relationship between the addresses and distortion compensation coefficients;

FIG. 4 is a schematic diagram illustrating an example of a convergence course of a feedback signal;

FIG. 5 is a flowchart illustrating an example of a coefficient updating process according to the first embodiment;

FIG. 6 is a block diagram illustrating an example of a distortion compensation device according to a second embodiment;

FIG. 7 is a schematic diagram illustrating an example of the threshold according to the second embodiment;

FIG. 8 is a flowchart illustrating an example of a coefficient updating process according to the second embodiment;

FIG. 9 is a schematic diagram illustrating an example of calculation timing of a threshold according to a third embodiment;

FIG. 10 is a schematic diagram illustrating another example of calculation timing of the threshold according to the third embodiment;

FIG. 11 is a block diagram illustrating an example of a distortion compensation device according to a fourth embodiment;

FIG. 12 is a schematic diagram illustrating an example of distribution of feedback coefficients according to the fourth embodiment;

FIG. 13 is a flowchart illustrating an example of a coefficient updating process according to the fourth embodiment;

FIG. 14 is a block diagram illustrating an example of a distortion compensation device according to a fifth embodiment;

FIG. 15 is a schematic diagram illustrating an example of distribution of the product of the absolute value of a feedback coefficient and a step coefficient according to the fifth embodiment;

FIG. 16 is a flowchart illustrating an example of a coefficient updating process according to the fifth embodiment;

FIG. 17 is a block diagram illustrating an example of a distortion compensation device according to a sixth embodiment;

FIG. 18 is a schematic diagram illustrating an example of distribution of the product of the absolute value of a feedback coefficient and a step coefficient according to the sixth embodiment;

FIG. 19 is a flowchart illustrating an example of a coefficient updating process according to the sixth embodiment;

FIG. 20 is a block diagram illustrating an example of a distortion compensation device according to a seventh embodiment;

FIG. 21 is a block diagram illustrating an example of a distortion compensation device according to an eighth embodiment; and

FIG. 22 is a block diagram illustrating an example of hardware the distortion compensation device.

### DESCRIPTION OF EMBODIMENTS

Preferred embodiments of the present invent ion will be explained with reference to accompanying drawings. Furthermore, the embodiments, described below do not limit the disclosed technology. Furthermore, each of the embodiments can be used in any appropriate combination as long as the processes do not conflict with each other.

### [a] First Embodiment

### Configuration of a Distortion Compensation Device 10

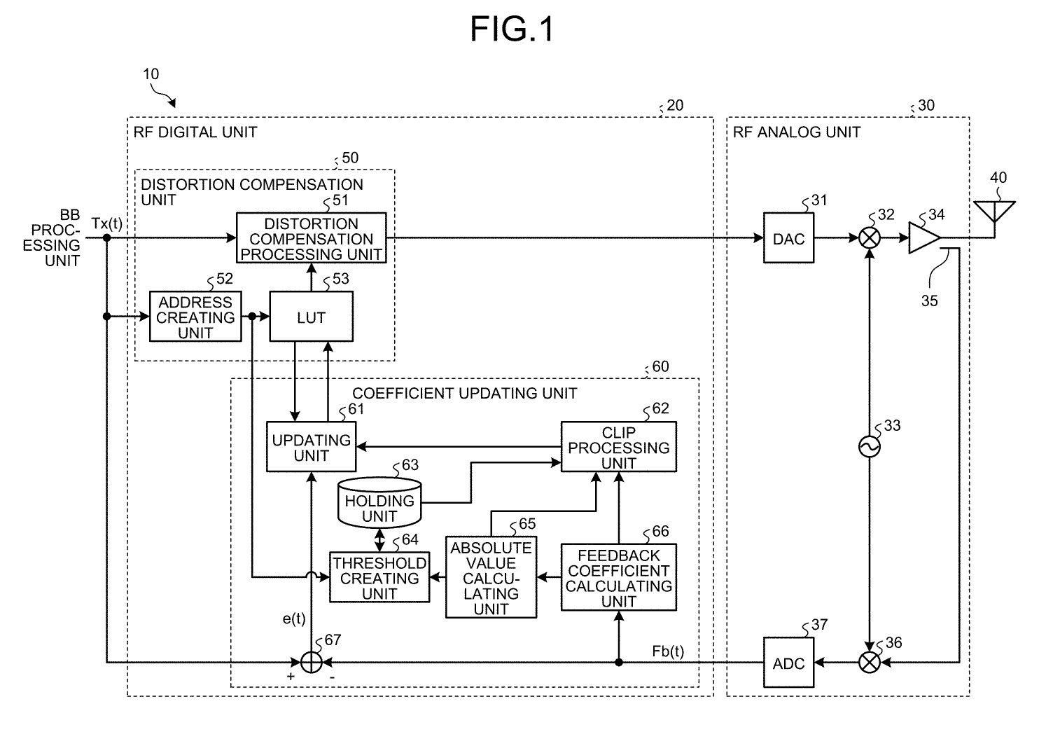

FIG. 1 is a block diagram illustrating an example of the distortion compensation device 10 according to a first embodiment. The distortion compensation device 10 according to the embodiment includes a Radio Frequency (RF) digital unit 20, an RF analog unit 30, and an antenna 40. The RF digital unit 20 includes a distortion compensation unit 50 and a coefficient updating unit 60.

The RF analog unit 30 includes a digital-to-analog converter (DAC) 31, a mixer 32, an oscillator 33, a power amplifier 34, a coupler 35, a mixer 36, and an ADC 37.

The DAC 31 converts, from a digital signal to an analog signal, the transmission signal that is output from the distortion compensation unit 50 and that has been subjected to distortion compensation. Then, the DAC 31 outputs the signal that has been converted to the analog signal to the mixer 32. The mixer 32 modulates and up converts, by using the local oscillator signal output from the oscillator 33, the signal output from the DAC 31. Then, the mixer 32 outputs the processed signal to the power amplifier 34. The power amplifier 34 amplifies the signal output from the mixer 32 by a predetermined amplification factor. The signal amplified by the power amplifier 34 is transmitted from the antenna 40.

A part of the signal amplified by the power amplifier 34 is fed back via the coupler 35. The mixer 36 down converts, by using the signal output from the oscillator 33, the signal that has been fed back via the coupler 35. The ADC 37 converts, from an analog signal to a digital signal, the signal that has been subjected to demodulation or the like by the mixer 36. Then, the ADC 37 outputs the feedback signal converted to the digital signal to the coefficient updating unit 60. The feedback signal output from the ADC 37 is defined as Fb(t). The feedback signal Fb(t) is an example of an output signal that has been output from the power amplifier 34.

The distortion compensation unit 50 includes a distortion compensation processing unit 51, an address creating unit 52, and a look up table (LUT) 53. The address creating unit 52 generates, based on the baseband transmission signal Tx(t) generated by a base band signal (BB) processing unit, a plurality of transmission signals Tx(t-j) each having a different amount of delay. Then, the address creating unit 52 creates the address for each of the transmission signals Tx(t-j) that have a plurality of different amounts of delay and that include the transmission signal Tx(t) having the amount of delay of zero. Furthermore, regarding the transmission signals Tx(t-j), j represents an amount of delay and takes a value of 0 to N. Then, the address creating unit 52 outputs the address created for each of the transmission signals Tx(t-j) and outputs the addresses to the LUT 53 and the coefficient updating unit 60. In the embodiment, the address creating unit 52 creates the address in accordance with the amplitude of each of the transmission signals Tx(t-j). The amplitude of the transmission signal Tx(t-j) is an example of the magnitude of the transmission signal Tx(t-j). Namely, the value of the addresses created by the address creating unit 52 are values that are in accordance with the magnitude of the corresponding transmission signals Tx(t-j). Furthermore, as another example, the address creating unit 52 may also create the address in accordance with the magnitude of the power of the delay signal.

The LUT 53 stores therein the distortion compensation coefficients that are associated with the addresses for each of the transmission signals Tx(t-j) having different amounts of delay. The LUT 53 outputs, to the distortion compensation processing unit 51 for each of the transmission signals Tx(t-j), the distortion compensation coefficient associated with the address output from the address creating unit 52. Each of the distortion compensation coefficients in the LUT 53 is updated by the coefficient updating unit 60 as needed. The LUT 53 is an example of a table.

The distortion compensation processing unit 51 generates, based on the transmission signal Tx(t) output from the BB processing unit, the transmission signals Tx(t-j) having a plurality of different amounts of delay. Then, for each of the transmission signals Tx(t-j) that have a plurality of different amounts of delay and that include the transmission signal Tx(t) having the amount of delay of zero, the distortion compensation processing unit 51 multiplies the distortion compensation coefficient output from the LUT 53 by the transmission signal Tx(t-j). Then, by adding the transmission signal Tx(t-j) in which the distortion compensation coefficient is multiplied, the distortion compensation processing unit 51 generates the transmission signal Tx′(t) that has been, subjected to distortion compensation. The transmission signal Tx′(t) that has been subjected to the distortion compensation is output to the DAC 31.

The coefficient updating unit 60 calculates an update amount of a distortion compensation coefficient for each of the plurality of the transmission signals Tx(t-j) each having a different amount of delay and then updates the distortion compensation coefficients in the LUT 53 by using the calculated update amount. The updated distortion compensation coefficient hⱼ(p) related to the transmission signal Tx(t-j) that is delayed by j samples is calculated based on, for example, Equation (1) below.

hⱼ(p)=h′ⱼ(p)+μ×e(t)×Cⱼ (1)

Here, in Equation (1) above, h′ⱼ(p) represents the distortion compensation, coefficient that is before the update and μ represents a step coefficient. Furthermore, in Equation (1) above, the error e(t) is calculated, by using the transmission signal Tx(t) and the feedback signal Fb(t), based on, for example, Equation (2) below.

e(t)=Tx(t)−Fb(t) (2)

Furthermore, in Equation (1) above, the feedback coefficient Cⱼ is calculated based on, for example, Equation (3) below by using each of the feedback signals Fb(t-j) associated with the transmission signals Tx(t-j) delayed by j samples.

$${C}_{j} = \frac{{Fb}^{*} ( i - j )}{\frac{1}{N} {\sum }_{k = 0}^{N} {\vert Fb ( t - k ) \vert}^{2}} \qquad ( 3 )$$

In Equation (3) above, Fb*(t-j) is a conjugate complex number of Fb(t-j).

In particular, the feedback coefficient C₀ calculated from the feedback signal Fb(t) with respect to transmission signal Tx(t) having an amount of delay of zero (i.e., j=0) is represented by, for example, Equation (4) below.

$${C}_{0} = \frac{{Fb}^{*} ( t )}{\frac{1}{N} {\sum }_{k = 0}^{N} {\vert Fb ( t - k ) \vert}^{2}} \qquad ( 4 )$$

In a process of updating the distortion compensation coefficients, the coefficient updating unit 60 according to the embodiment performs a clip process, for each of the transmission signals Tx(t-j), such that the absolute value of the feedback coefficient Cⱼ becomes equal to or less than a predetermined threshold Cₜₕ. In the following, the coefficient updating unit 60 according to the embodiment will be described in detail below.

The coefficient updating unit 60 according to the embodiment includes, for example, as illustrated in FIG. 1, an updating unit 61, a clip processing unit 62, a holding unit 63, a threshold creating unit 64, an absolute value calculating unit 65, a feedback coefficient calculating unit 66, and a subtracter 67.

The feedback coefficient calculating unit 66 calculates the feedback coefficient Cⱼ for each of the transmission signals Tx(t-j) associated with the corresponding feedback signals Fb(t-j) by performing the arithmetic operation based on Equation (3) described above by using the feedback signal Fb(t-j) output from the ADC 37. Then, the feedback coefficient calculating unit 66 outputs the calculated feedback coefficient Cⱼ to the clip processing unit 62 and the absolute value calculating unit 65. The feedback coefficient calculating unit 66 is an example of a calculating unit.

The absolute value calculating unit 65 calculates, for each of the transmission signals Tx(t-j), the absolute value |Cⱼ| of the feedback coefficient Cⱼ output from the feedback coefficient calculating unit 66. Then, the absolute value calculating unit 65 outputs the absolute value |Cⱼ| calculated for each of the transmission signals Tx(t-j) to the clip processing unit 62 and the threshold creating unit 64.

The holding unit 63 stores therein the threshold Cₜₕ for each of the transmission signals Tx(t-j). The threshold creating unit 64 creates, for each of the transmission signals Tx(t-j), the threshold Cₜₕ based on the address output from the address creating unit 52 and based on the absolute value |Cⱼ| output from the absolute value calculating unit 65. For example, the threshold creating unit 64 performs, at each predetermined timing, the following process regarding a predetermined number of samples counted from the top (for example, 100 samples) of each of the transmission signals Tx(t-j).

First, the threshold creating unit 64 initializes the value of the threshold Cₜₕ of each of the transmission signals Tx(t-j) in the holding unit 63 to zero. Then, the threshold creating unit 64 refers to the address from the address creating unit 52 for each of the transmission signals Tx(t-j) and determines whether the absolute value |Cⱼ| is the absolute value |Cⱼ| that is calculated from the feedback signal Fb(t-j) associated with the transmission signal Tx(t-j) having the address greater than the threshold Aₜₕ. The threshold Aₜₕ of the address is previously set in the threshold creating unit 64 by an administrator or the like of the distortion compensation device 10.

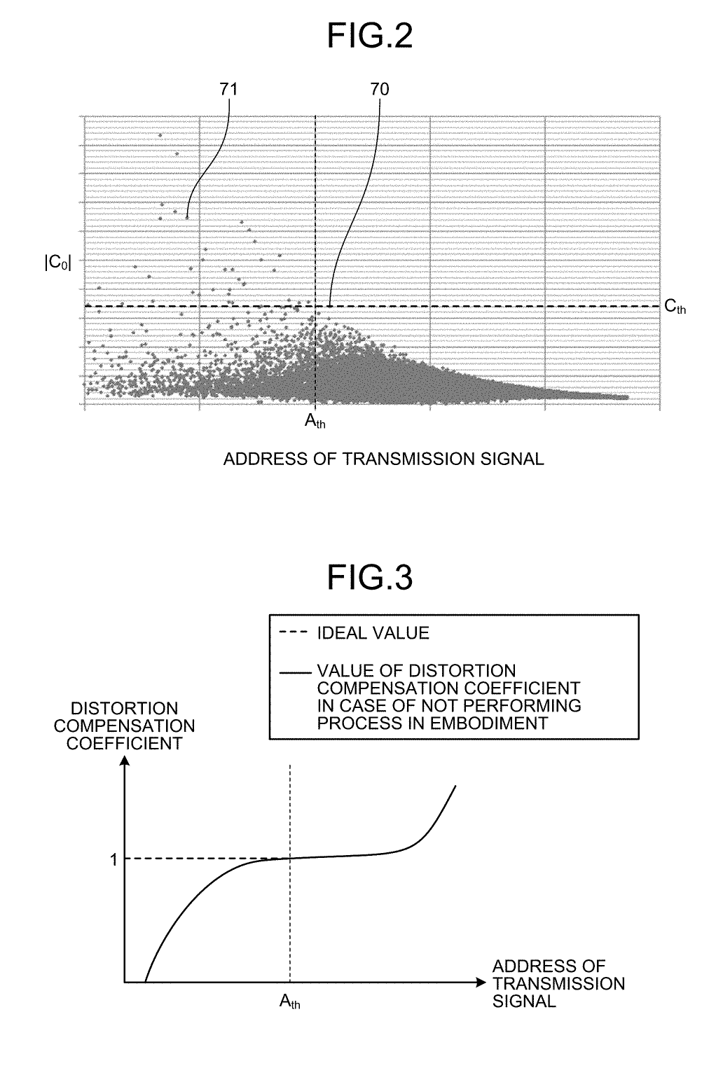

If the absolute value |Cⱼ| is the absolute value |Cⱼ| that is calculated from the feedback signal Fb(t-j) associated with the transmission signal Tx(t-j) having the address greater than the threshold Aₜₕ, the threshold creating unit 64 compares, for each of the transmission signals Tx(t-j), the subject absolute value |Cⱼ| with the threshold Cₜₕ stored in the holding unit 63. If the value of the absolute value |Cⱼ| is greater than the value of the threshold Cₜₕ stored in the holding unit 63, the threshold creating unit 64 stores the value of the absolute value |Cⱼ| as the threshold Cₜₕ in the holding unit 63. Consequently, if the determination about the predetermined number of samples of each of the transmission signals Tx(t-j) has been completed, for example, the threshold Cₜₕ for each of the transmission signals Tx(t-j) illustrated in FIG. 2 is stored in the holding unit 63.

FIG. 2 is a schematic diagram illustrating an example of a threshold according to the first embodiment. FIG. 2 illustrates an example of the distribution of the absolute value |C₀| calculated from the feedback signal Fb(t) associated with the transmission signal Tx(t) having the amount of delay of zero. Furthermore, regarding the absolute value |Cⱼ| calculated from the feedback signals Fb(t-j) associated with the transmission signals Tx(t-j) having another amount of delay, the same distribution as that illustrated in FIG. 2 is obtained. In the embodiment, for example, as illustrated in FIG. 2, the value of the maximum value with the absolute value |C₀| (for example, the absolute value |C₀| indicated by a point 70 illustrated in FIG. 2) is used as the value of the threshold Cₜₕ from among the absolute values |C₀| associated with the addresses greater than the threshold Aₜₕ.

In the following, an example of a method of deciding the threshold Aₜₕ of the address will be described. FIG. 3 is a schematic diagram illustrating the relationship between the addresses and distortion compensation coefficients. In the feedback signal Fb(t) that is fed back from the power amplifier 34, a noise component generated due to, for example, thermal noise of the ADC 37, or the like is included. In the power amplifier 34, because the transmission signal Tx′(t) that has been subjected to distortion compensation is amplified at a predetermined amplification factor, if the amplitude of the transmission signal Tx(t) is small, i.e., if the value of the address created from the transmission signal Tx(t) is small, the power of the feedback signal Fb(t) becomes small. If the power of the feedback signal Fb(t) is small, the SN ratio becomes small and the influence of the noise component becomes large.

The power amplifier 34 generally exhibits a nonlinear characteristic in a saturation region in which the amplitude of an input signal is large, whereas, the power amplifier 34 generally exhibits a linear characteristic in a region in which the amplitude of an input signal is small. Consequently, ideally, for example, as indicated by the broken line illustrated in FIG. 3, in the region in which the amplitude of the input signal is small, the distortion compensation coefficient becomes a constant value (for example 1).

However, if the amplitude of the transmission signal Tx(t) is small, i.e., if the value of the address of the transmission signal Tx(t) is small, because the influence of the noise component included in the feedback signal Fb(t) becomes large, for example, as indicated by the solid line illustrated in FIG. 3, the distortion compensation coefficient is updated to the value different from an ideal value. In the embodiment, if the value of the address of the transmission signal Tx(t) is made small, for example, the value of the address in which the distortion compensation coefficient starts to shift from the ideal value is previously decided sis the threshold Aₜₕ. As an example of a specific value, for example, the upper limit of the addresses present in the range of about 40% of the address having a smaller value out of the entire range of the addresses may also be used as the threshold Aₜₕ. For example, if the entire range of the address is 1 to 100, the value of the address of 40 may also be used as the threshold Aₜₕ.

The clip processing unit 62 receives, for each of the transmission signals Tx(t-j), the feedback coefficient Cⱼ from the feedback coefficient calculating unit 66 and receives the absolute value |Cⱼ| of the feedback coefficient Cⱼ from the absolute value calculating unit 65. Then, the clip processing unit 62 compares, for each of the transmission signals Tx(t-j), the absolute value |Cⱼ| received from the absolute value calculating unit 65 with the threshold Cₜₕ that is stored in the holding unit 63. If the value of the absolute value |Cⱼ| is equal to or less than the value of the threshold Cₜₕ, the clip processing unit 62 outputs the feedback coefficient Cⱼ received from the feedback coefficient calculating unit 66 to the updating unit 61.

In contrast, if the value of the absolute value |Cⱼ| is greater than the value of the threshold Cₜₕ, the clip processing unit 62 performs a clip process that calculates a feedback coefficient Cⱼ′ based on Equation (5) below.

$${C}_{j}^{′} = \frac{{C}_{j}}{\vert {C}_{j} \vert} \times {C}_{th} \qquad ( 5 )$$

Regarding the feedback coefficient Cⱼ′ calculated based on Equation (5) above, the absolute value |Cⱼ′| that is the magnitude of the feedback coefficient Cⱼ′ is equal to the threshold Cₜₕ and the phase is the same as that of the original feedback coefficient Cⱼ. Then, the clip processing unit 62 outputs the feedback coefficient Cⱼ′ that has been subjected to the clip process to the updating unit 61.

Consequently, example, as illustrated in FIG. 2, the feedback coefficient C₀ (for example, a point 71, or the like) having the value of the absolute value |C₀| greater than the value of the threshold Cₜₕ is clipped such that the absolute value is equal to the threshold Cₜₕ while maintaining the phase of the feedback coefficient C₀.

The subtracter 67 calculates an error e(t) by performing the arithmetic operation indicated by Equation (2) described above. Then, the subtracter 67 outputs the calculated error e(t) to the updating unit 61.

The updating unit 61 receives the feedback coefficient Cⱼ from the clip processing unit 62, receives the error e(t) from the subtracter 67, and reads the distortion compensation coefficient h′ⱼ(p) that is before an update from the LUT 53. Then, the updating unit 61 calculates an updated distortion compensation coefficient hⱼ(p) by performing the arithmetic operation indicated by Equation (1) described above. Then, the updating unit 61 updates the distortion compensation coefficient h′ⱼ(p) in the LUT 53 by using the calculated distortion compensation coefficient hⱼ(p). Furthermore, in the embodiment, step coefficient μ is previously set in the updating unit 61 by an administrator of the distortion compensation device 10 or the like. Furthermore, if the updating unit 61 receives the feedback coefficient Cⱼ′ from the clip processing unit 62, the updating unit 61 calculates an updated distortion compensation coefficient hⱼ(p) by using, instead of the feedback coefficient Cⱼ, the feedback coefficient Cⱼ′ in Equation (1) described above.

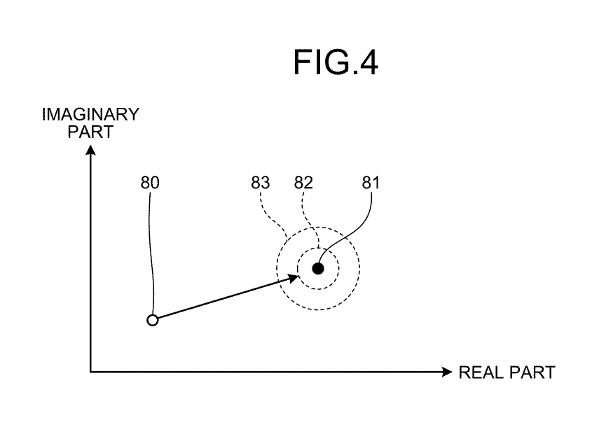

Here, for example, as illustrated in FIG. 4, in the process of updating the distortion compensation coefficient, regarding a feedback signal 80, the distortion compensation coefficient is updated so as to approach a transmission signal 81 on the IQ plane. FIG. 4 is a schematic diagram illustrating an example of a convergence course of the feedback signal 80. If the SN ratio of the feedback signal 80 is small, for example, as illustrated in FIG. 4, the feedback signal 80 varies in a range 83 centered on the transmission signal 81. Consequently, when the feedback signal 80 is viewed at a certain moment, the feedback signal 80 is sometimes present at the position away from the transmission signal 81 that corresponds to the correct solution.

In contrast, in the embodiment, in the process of updating the distortion compensation coefficient, the clip process is performed such that the absolute value |Cⱼ| of the feedback coefficient Cⱼ is equal to or less than a predetermined threshold Cₜₕ. Consequently, for example, as illustrated in FIG. 4, the feedback signal 80 varies within a range 82, which is narrower than the range 83, centered on the transmission signal 81. Consequently, when the feedback signal 80 is viewed at a certain moment, the feedback signal 80 is present at the position closer to the range 83. Consequently, the feedback signal 80, i.e., a distortion component included in the signal output from the power amplifier 34, is decreased and the characteristic of the ACLR or the like is improved.

### Coefficient Updating Process

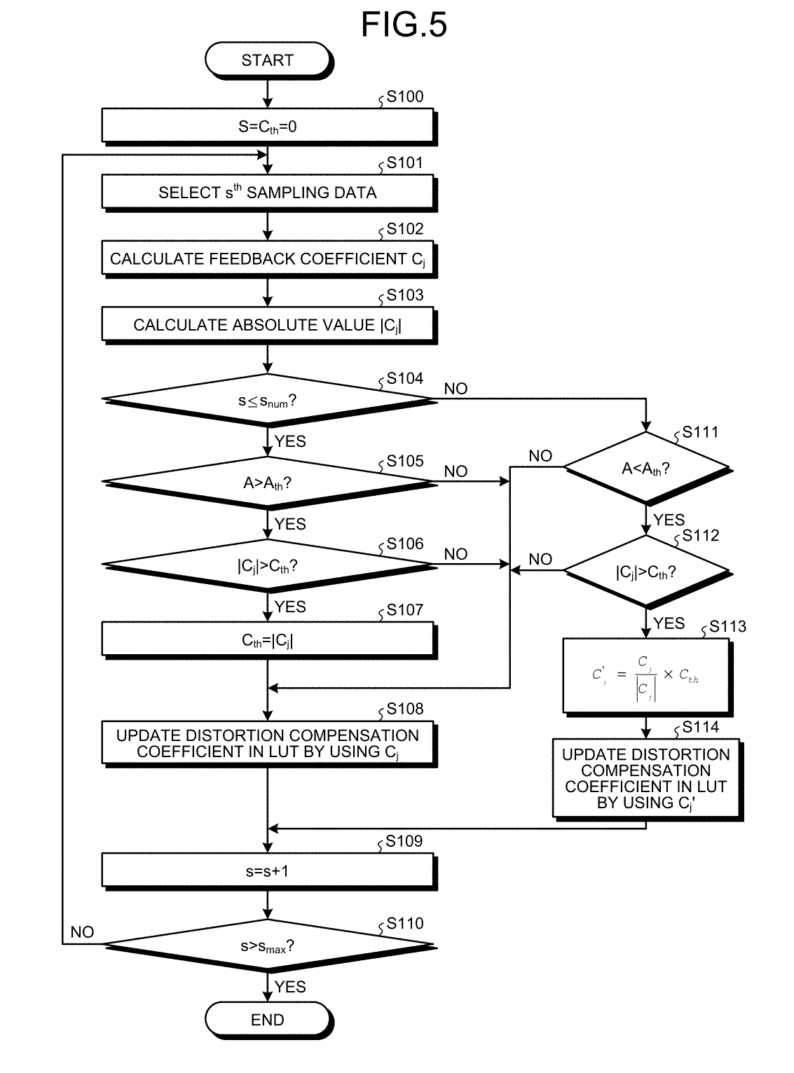

FIG. 5 is a flowchart illustrating an example of a coefficient updating process according to the first embodiment. The distortion compensation device 10 performs the coefficient updating process illustrated in FIG. 5 at each predetermined timing. For example, if the distortion compensation device 10 transmits a downlink (DL) signal in the mobile communication system, such as long term evolution (LTE), or the like, the distortion compensation device 10 performs the coefficient updating process illustrated in FIG. 5 for each, for example, single frame. Furthermore, in the following flowchart, a description will be given of the transmission signal Tx(t-j) delayed by j samples and given of the feedback signal Fb(t-j); however, the same process is also performed on each of the delay signals delayed by j represented by 0 to N.

First, the feedback coefficient calculating unit 66 initializes the variable s that counts the pieces of sampling data of the transmission signal Tx(t-j) to zero (Step S100). Furthermore, the threshold creating unit 64 initializes the value of the threshold Cₜₕ in the holding unit 63 to zero (Step S100).

Then, the feedback coefficient calculating unit 66 selects the sampling data of the feedback signal Fb(t-j) that is associated with the sampling data of the s^{th} transmission signal Tx(t-j) (Step S101). Then, by performing the arithmetic operation indicated by Equation (3) described above by using the sampling data of the feedback signal Fb(t-j) selected at Step S101, the feedback coefficient calculating unit 66 calculates the feedback coefficient Cⱼ (Step S102). Then, the feedback coefficient calculating unit 66 outputs the calculated feedback coefficient Cⱼ to the absolute value calculating unit 65.

Then, the absolute value calculating unit 65 calculates the absolute value |Cⱼ| of the feedback coefficient Cⱼ output from the feedback coefficient calculating unit 66 (Step S103). Then, the absolute value calculating unit 65 outputs the calculated absolute value |Cⱼ| to the clip processing unit 62 and the threshold creating unit 64.

Then, the clip processing unit 62 and the threshold creating unit 64 determine whether the value of the variable s is equal to or less than the reference value sₙᵤₘ (Step S104). In the embodiment, the reference value sₙᵤₘ for example, 100. If the value of the variable s is equal to or less than the reference value sₙᵤₘ (Yes at Step S104), the threshold creating unit 64 determines whether the value A of the address of the s^{th} transmission signal Tx(t-j) is greater than the value of the threshold Aₜₕ of the address (Step S105). If the value A of the address of the s^{th} transmission signal Tx(t-j) is equal to or less than the value of the threshold Aₜₕ of the address (No at Step S105), the clip processing unit 62 performs the process indicated at Step S108.

In contrast, if the value A of the address of the s^{th} transmission signal Tx(t-j) is greater than the value of the threshold Aₜₕ of the address (Yes at Step S105), the threshold creating unit 64 reads the threshold Cₜₕ from the holding unit 63. Then, the threshold creating unit 64 determines whether the value of the absolute value |Cⱼ| of the feedback coefficient Cⱼ output from the absolute value calculating unit 65 is greater than the value of the threshold Cₜₕ (Step S106). If the value of the absolute value |Cⱼ| is equal to or less than the value of the threshold Cₜₕ (No at Step S106), the updating unit 61 performs the process indicated at Step S108.

In contrast, if the value of the absolute value |Cⱼ| is greater than the value of the threshold Cₜₕ (Yes at Step S106), the threshold creating unit 64 substitutes the value of the threshold Cₜₕ in the holding unit 63 for the value of the absolute value |Cⱼ| of the feedback coefficient Cⱼ output from the absolute value calculating unit 65 (Step S107).

Then, the clip processing unit 62 outputs, to the updating unit 61, the feedback coefficient Cⱼ that is output from the feedback coefficient calculating unit 66. By performing the arithmetic operation indicated by Equation (1) described above by using the feedback coefficient Cⱼ output from the clip processing unit 62, the updating unit 61 calculates the updated distortion compensation coefficient hⱼ(p). Then, the updating unit 61 updates the distortion compensation coefficient h′ⱼ(p) in the LUT 53 to the calculated distortion compensation coefficient hⱼ(p) (Step S108).

Then, the feedback coefficient calculating unit 66 increments the variable s by 1 (Step S109). Then, the feedback coefficient calculating unit 66 determines whether the value of the variable s is greater than sₘₐₓ that is the maximum value of the variable s (Step S110). In the embodiment, sₘₐₓ is the number of samples in a single frame and is, for example, 1000. If the value of the variable s is equal to or less than the value of sₘₐₓ (No at Step S110), the feedback coefficient calculating unit 66 again performs the process indicated at Step S101. In contrast, if the value of the variable s is greater than the value of sₘₐₓ (Yes at Step S110), the distortion compensation device 10 ends the process illustrated in the subject flowchart.

At Step S104, if the value of the variable s is greater than the reference value sₙᵤₘ (No at Step S104), the clip processing unit 62 determines whether the value A of the address of the s^{th} transmission signal Tx(t-j) is less than the value of the threshold Aₜₕ of the address (Step S111). If the value A of the address of the s^{th} transmission signal Tx(t-j) is equal to or greater than the value of the threshold Aₜₕ of the address (No at Step S111), the clip processing unit 62 performs the process indicated at Step S108.

In contrast, if the value A of the address of the s^{th} transmission signal Tx(t-j) is less than the value of the threshold Aₜₕ of the address (Yes at Step S111), the clip processing unit 62 reads the threshold Cₜₕ from the holding unit 63. Then, the clip processing unit 62 determines whether the value of the absolute value |Cⱼ| of the feedback coefficient Cⱼ output from the absolute value calculating unit 65 is greater than the value of the threshold Cₜₕ (Step S112). If the value of the absolute value |Cⱼ| is equal to or less than the value of the threshold Cₜₕ (No at Step S112), the clip processing unit 62 performs the process indicated at Step S108.

In contrast, if the value of the absolute value |Cⱼ| is greater than the value of the threshold Cₜₕ (Yes at Step S112), the clip processing unit 62 performs the arithmetic operation indicated by Equation (5) described above (Step S113). Consequently, the feedback coefficient Cⱼ′ is created by being clipped such that the absolute value becomes the threshold Cₜₕ while maintaining the phase of the feedback coefficient Cⱼ. Then, the clip processing unit 62 outputs the feedback coefficient Cⱼ′ to the updating unit 61.

Then, the updating unit 61 calculates the updated distortion compensation, coefficient hⱼ(p) indicated by Equation (1) described above by using the feedback coefficient Cⱼ′ output from the clip processing unit 62. Then, the updating unit 61 updates the distortion compensation coefficients h′ⱼ(p) in the LUT 53 by using the calculated distortion compensation coefficient hⱼ(p) (Step S114). Then, the threshold creating unit 64 and the feedback coefficient calculating unit 66 performs the process indicated at Step S109.

### Effects of the First Embodiment

As is clear from the description above, the distortion compensation device 10 according to the embodiment includes the LUT 53, the feedback coefficient calculating unit 66, the clip processing unit 62, and the updating unit 61. The LUT 53 stores therein the distortion compensation coefficients. The feedback coefficient calculating unit 66 calculates the feedback coefficient Cⱼ based on the output signal from the power amplifier 34. If the absolute value |Cⱼ| of the feedback coefficient Cⱼ calculated by the feedback coefficient calculating unit 66 is equal to or less than the threshold Cₜₕ, the clip processing unit 62 outputs the feedback coefficient Cⱼ calculated by the feedback coefficient calculating unit 66. Furthermore, if the absolute value |Cⱼ| of the feedback coefficient Cⱼ calculated by the feedback coefficient calculating unit 66 is greater than the threshold Cₜₕ, the clip processing unit 62 outputs the feedback coefficient Cⱼ′ of which absolute value is equal to or less than the threshold Cₜₕ. The updating unit 61 updates the distortion compensation coefficients in the LUT 53 by using the error between the transmission signal that has not been subjected to distortion compensation and the output signal that is output from the power amplifier 34, by using a predetermined step coefficient, and by using the feedback coefficient output from the clip processing unit 62. Consequently, the distortion compensation device 10 can improve the quality of the signal transmitted from the distortion compensation device 10.

Furthermore, in the distortion compensation device 10 according to the embodiment, if the absolute value |Cⱼ| of the feedback coefficient Cⱼ calculated by the feedback coefficient calculating unit 66 is greater than the threshold Cₜₕ, regarding the subject feedback coefficient Cⱼ, the clip processing unit 62 calculates, by performing the clip process, the feedback coefficient of which absolute value is the threshold Cₜₕ. The clip process in the embodiment is the process of, for example, multiplying the threshold Cₜₕ by the value that is obtained by dividing the feedback coefficient Cⱼ calculated by the feedback coefficient calculating unit 66 by the absolute value |Cⱼ| of the subject feedback coefficient Cⱼ. Consequently, continuity of the phase of the feedback coefficient Cⱼ′ is maintained even after the clip process and thus it is possible to suppress the degradation of the quality of the signal.

Furthermore, in the distortion compensation device 10 according to the embodiment, the clip processing unit 62 uses, as the threshold Cₜₕ, the maximum value of the absolute value |Cⱼ| of the feedback coefficient Cⱼ calculated based on the output signal that is associated with the transmission signal Tx(t-j) related to the address that is greater than the threshold Aₜₕ from among the samples of a predetermined number of the transmission signals Tx(t-j). Consequently, the distortion compensation device 10 can improve the quality of the signal transmitted from the distortion compensation device 10.

### [b] Second Embodiment

### Configuration of the Distortion Compensation Device 10

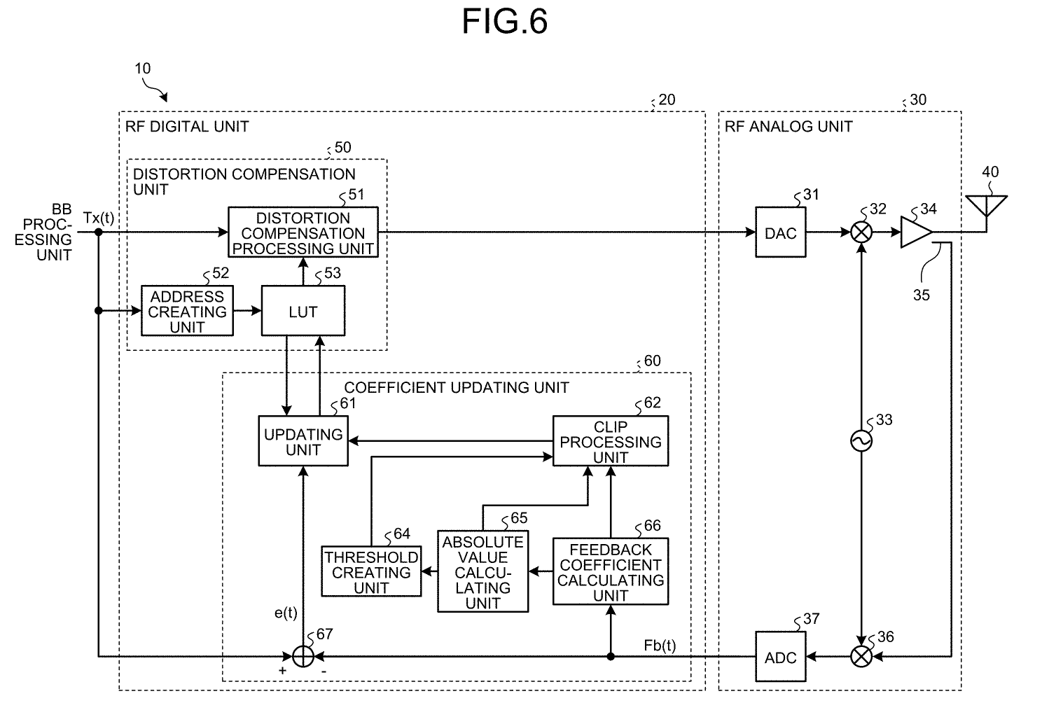

FIG. 6 is a block, diagram illustrating an example of the distortion compensation device 10 according to a second embodiment. In the distortion, compensation device 10 according to the embodiment, the configuration of the coefficient updating unit 60 is different that of the distortion compensation device 10 according to the first embodiment. Furthermore, the blocks illustrated in FIG. 6 having the same reference numerals as those illustrated in FIG. 1 have the same configuration as the blocks illustrated in FIG. 1 except for the following points described below; therefore, descriptions thereof will be omitted.

The coefficient updating unit 60 according to the embodiment includes the updating unit 61, the clip processing unit 62, the threshold creating unit 64, the absolute value calculating unit 65, the feedback coefficient calculating unit 66, and the subtracter 67. The threshold creating unit 64 creates the threshold Cₜₕ based on the absolute value |Cⱼ| that is output from the absolute value calculating unit 65.

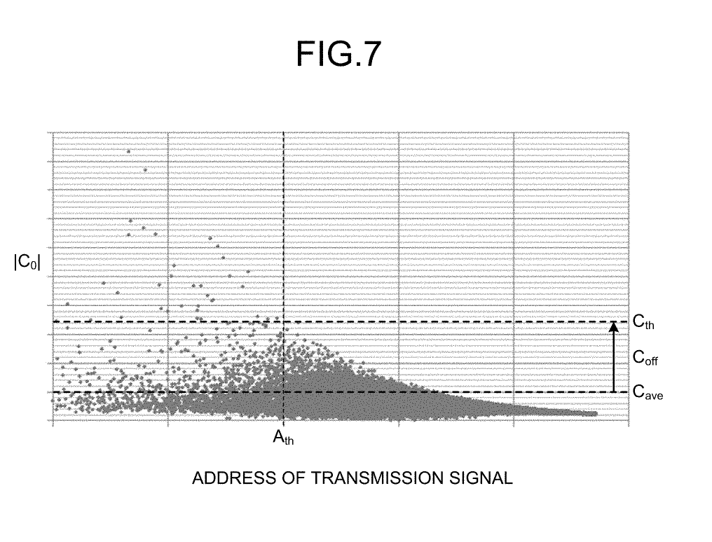

Specifically, regarding the predetermined number of samples counted from the top (for example, 100 samples) of each of the transmission signals Tx(t-j), the threshold creating unit 64 calculates, at each predetermined timing, the average value Cₐᵥₑ by using the absolute value |Cⱼ| that is calculated from the feedback signal Fb(t-j). Then, the threshold creating unit 64 calculates, for each of the transmission signals Tx(t-j), for example, as illustrated in FIG. 7, the threshold Cₜₕ by adding a predetermined offset C_{off} to the calculated average value Cₐᵥₑ. FIG. 7 is a schematic diagram illustrating an example of the threshold according to the second embodiment. Then, the threshold creating unit 64 outputs the threshold Cₜₕ calculated for each of the transmission signals Tx(t-j) to the clip processing unit 62.

Furthermore, the offset C_{off} is set to the value in which, for example, in the standard environment, the threshold Cₜₕ of each of the transmission signals Tx(t-j) becomes the maximum value of the absolute value |Cⱼ| that is calculated from the feedback signal Fb(t-j) associated with the transmission signal Tx(t-j) having the address equal to or greater than the threshold Aₜₕ. The value of the offset C_{off} is previously set in the threshold creating unit 64 by an administrator of the distortion compensation device 10, or the like.

Here, in each of the transmission signals Tx(t-j), from among the feedback coefficients Cⱼ, there may sometimes be the feedback coefficient Cⱼ having a temporarily greater value of the absolute value |Cⱼ| due to instantaneous noise. In such a case, if it is assumed that the maximum value of the absolute value |Cⱼ| associated with the value of the address equal to or greater than the threshold Aₜₕ is decided as the threshold Cₜₕ, the absolute value |Cⱼ| that temporarily becomes a great value due to instantaneous noise is decided as the threshold Cₜₕ. In such a case, the threshold Cₜₕ is maintained as a fixed large value until the subsequent calculation of the threshold Cₜₕ is performed. If the threshold Cₜₕ is maintained as the fixed large value, the absolute value |Cⱼ| of the feedback coefficient Cⱼ obtained after the clip process does not particularly become small and thus the quality of the signal transmitted from the distortion compensation device 10 is not so improved.

In contrast, in the distortion compensation device 10 according to the embodiment, regarding the predetermined number of samples counted from the top of each of the transmission signals Tx(t-j), the threshold creating unit 64 calculates the average value Cₐᵥₑ about the absolute value |Cⱼ| calculated from the feedback signal Fb(t-j) associated with the transmission signal Tx(t-j). Then, the threshold creating unit 64 calculates the threshold Cₜₕ by adding the predetermined offset C_{off} to the calculated average value Cₐᵥₑ. Consequently, in the process of calculating the threshold Cₜₕ, the variation in the threshold Cₜₕ due to the influence of the absolute value |Cⱼ| that temporarily becomes a greater value due to instantaneous noise, can be kept low. Consequently, the quality of the signal transmitted from the distortion compensation device 10 can be more stably improved.

### Coefficient Updating Process

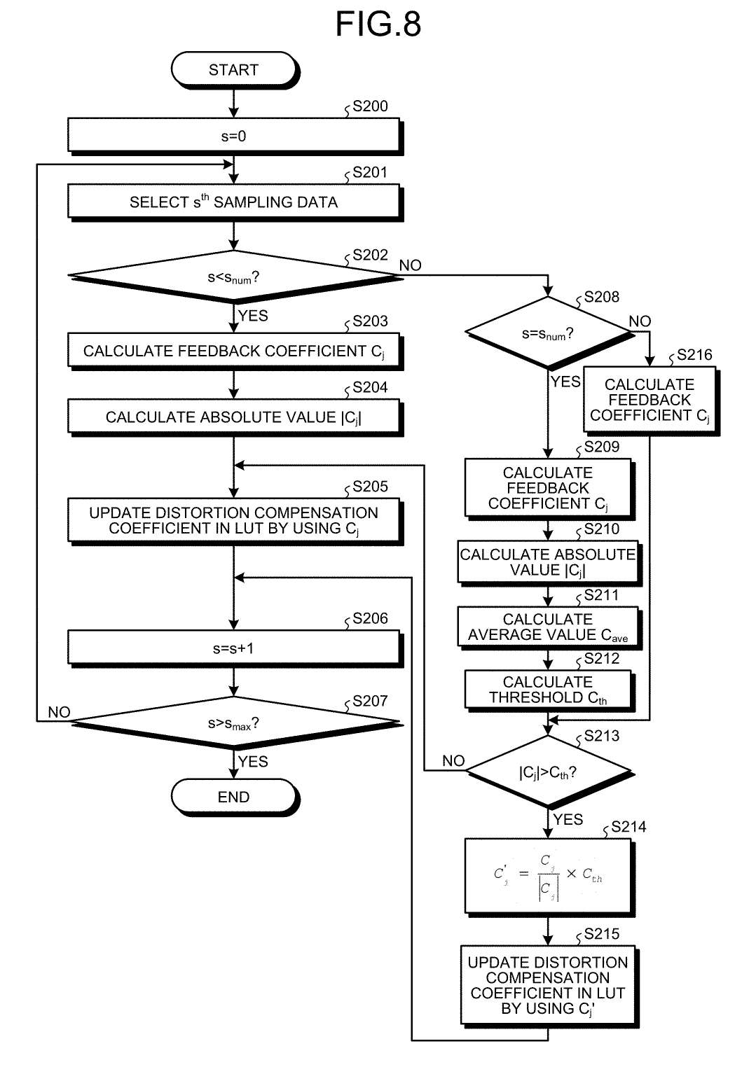

FIG. 8 is a flowchart illustrating an example of a coefficient updating process according to the second embodiment. The distortion compensation device 10 performs, at each predetermined timing, the coefficient updating process illustrated in FIG. 8. For example, if the distortion compensation device 10 transmits a DL signal in the mobile communication system, such as LTE, or the like, the distortion compensation device 10 performs, for example, for each frame, the coefficient updating process illustrated in FIG. 8. Furthermore, in the following flowchart, a description will be given of the transmission signal Tx(t-j) delayed by j samples and the feedback signal Fb(t-j); however, the same process is also performed on each of the delay signals delayed by j represented by 0 to N.

First, the feedback coefficient calculating unit 66 initializes the variable s that counts the pieces of sampling data of the transmission signal Tx(t-j) to zero (Step S200). Then, the feedback coefficient calculating unit 66 selects the sampling data of the feedback signal Fb(t-j) that is associated with the sampling data of the s^{th} transmission signal Tx(t-j) (Step S201). Then, the feedback coefficient calculating unit 66 determines whether the value of the variable s is less than the reference value sₙᵤₘ (Step S202). In the embodiment, the reference value sₙᵤₘ is, for example, 100.

If the value of the variable s is less than the reference value sₙᵤₘ (Yes at Step S202), the feedback coefficient calculating unit 66 performs arithmetic operation indicated by Equation (3) described above by using the sampling data of the feedback signal Fb(t-j) selected at Step S201. Consequently, the feedback coefficient Cⱼ is calculated (Step S203). Then, the feedback coefficient calculating unit 66 outputs the calculated feedback coefficient Cⱼ to the absolute value calculating unit 65.

Then, the absolute value calculating unit 65 calculates the absolute value |Cⱼ| of the feedback coefficient Cⱼ output from the feedback coefficient calculating unit 66 (Step S204). Then, the absolute value calculating unit 65 outputs the calculated absolute value |Cⱼ| to the threshold creating unit 64. The threshold creating unit 64 holds the absolute value |Cⱼ| output from the absolute value calculating unit 65.

Then, the clip processing unit 62 outputs, the updating unit 61, the feedback coefficient Cⱼ output from the feedback coefficient calculating unit 66. The updating unit 61 calculates the updated distortion compensation coefficient hⱼ(p) by performing the arithmetic operation indicated by Equation (1) described above by using the feedback coefficient Cⱼ output from the clip processing unit 62. Then, the updating unit 61 updates the distortion compensation coefficient h′ⱼ(p) in the LUT 53 by using the calculated distortion compensation coefficient hⱼ(p) (Step S205).

Then, the feedback coefficient calculating unit 66 increments the variable s by 1 (Step S206). Then, the feedback coefficient calculating unit 66 determines whether the value of the variable s is greater than sₘₐₓ that is the maximum value of the variable s (Step S207). In the embodiment, sₘₐₓ is the number of samples in a single frame and is, for example, 1000. If the value of the variable s is equal to or less than the value of sₘₐₓ (No at Step S207), the feedback coefficient calculating unit 66 again performs the process indicated at Step S201. In contrast, if the value of the variable s is greater than the value of sₘₐₓ (Yes at Step S207), the distortion compensation device 10 ends the process illustrated in the subject flowchart.

At Step S202, if the value of the variable s is equal to or greater than the reference value sₙᵤₘ (No at Step S202), the feedback coefficient calculating unit 66 determines whether the value of the variable s is equal to the reference value sₙᵤₘ (Step S208). If the value of the variable s is equal to the reference value sₙᵤₘ (Yes at Step S208), the feedback coefficient calculating unit 66 performs the arithmetic operation indicated by Equation (3) described above by using the sampling data of the feedback signal Fb(t-j) selected at Step S201. Consequently, the feedback coefficient Cⱼ is calculated (Step S209). Then, the feedback coefficient calculating unit 66 outputs the calculated feedback coefficient Cⱼ to the absolute value calculating unit 65.

Then, the absolute value calculating unit 65 calculates the absolute value |Cⱼ| of the feedback coefficient Cⱼ output from the feedback coefficient calculating unit 66 (Step S210). Then, the absolute value calculating unit 65 outputs the calculated absolute value |Cⱼ| to the clip processing unit 62 and the threshold creating unit 64.

Then, the threshold creating unit 64 calculates the average value Cₐᵥₑ of the absolute values |Cⱼ| by using the absolute value |Cⱼ| output from the absolute value calculating unit 65 and by using the holding absolute value |Cⱼ| (Step S211). Then, the threshold creating unit 64 calculates the threshold Cₜₕ by adding the offset C_{off} to the average value Cₐᵥₑ (Step S212). Then, the threshold creating unit 64 outputs the calculated threshold Cₜₕ to the clip processing unit 62.

Then, the clip processing unit 62 determines whether the value of the absolute value |Cⱼ| of the feedback coefficient Cⱼ output from the absolute value calculating unit 65 is greater than the value of the threshold Cₜₕ output from the threshold creating unit 64 (Step S213). If the value of the absolute value |Cⱼ| is equal to or less than the value of the threshold Cₜₕ (No at Step S213), the clip processing unit 62 performs the process indicated at Step S205.

In contrast, if the value of the absolute value |Cⱼ| is greater than the value of the threshold Cₜₕ (Yes at Step S213), the clip processing unit 62 performs the arithmetic operation indicated by Equation (5) described above (Step S214). Consequently, the clip process of clipping is performed, while maintaining the phase of the feedback coefficient Cⱼ, such that the absolute value of the feedback coefficient Cⱼ becomes the threshold Cₜₕ. Then, the clip processing unit 62 outputs the feedback coefficient ty that is clipped at the threshold Cₜₕ to the updating unit 61.

Then, the updating unit 61 calculates the updated distortion compensation coefficient hⱼ(p) by performing the arithmetic operation indicated by Equation (1) described above by using the feedback coefficient Cⱼ′ output from the clip processing unit 62. Then, the updating unit 61 updates the distortion compensation coefficient h′ⱼ(p) in the LUT 53 by using the calculated distortion compensation coefficient hⱼ(p) (Step S215). Then, the threshold creating unit 64 and the feedback coefficient calculating unit 66 performs the process indicated at Step S206.

### Effects of the Second Embodiment

As is clear from the description above, in the distortion compensation device 10 according to the embodiment, regarding the predetermined number of samples of the transmission signals, the clip processing unit 62 uses, as the threshold Cₜₕ, the value obtained by adding the predetermined offset C_{off} to the average value Cₐᵥₑ of the absolute values of the feedback coefficients calculated based on the output signal that is associated with the transmission signal. Consequently, it is possible to more stably improve the quality of the signal transmitted from the distortion compensation device 10.

### [c] Third Embodiment

In the first and the second embodiments described above, as described by using, for example, FIG. 5 or 8, the threshold Cₜₕ is calculated for each first period, such as the period of a single frame, or the like, by using samples in the beginning of a second period in a first period. Then, in the first period and in the remaining period after the second period has elapsed, the clip process is performed by using the threshold Cₜₕ that is calculated in the second period. In contrast, in the third embodiment, the threshold Cₜₕ calculated in the beginning of the second period in the first period is used for the clip process until the threshold Cₜₕ is calculated in the beginning of the second period in the first period.

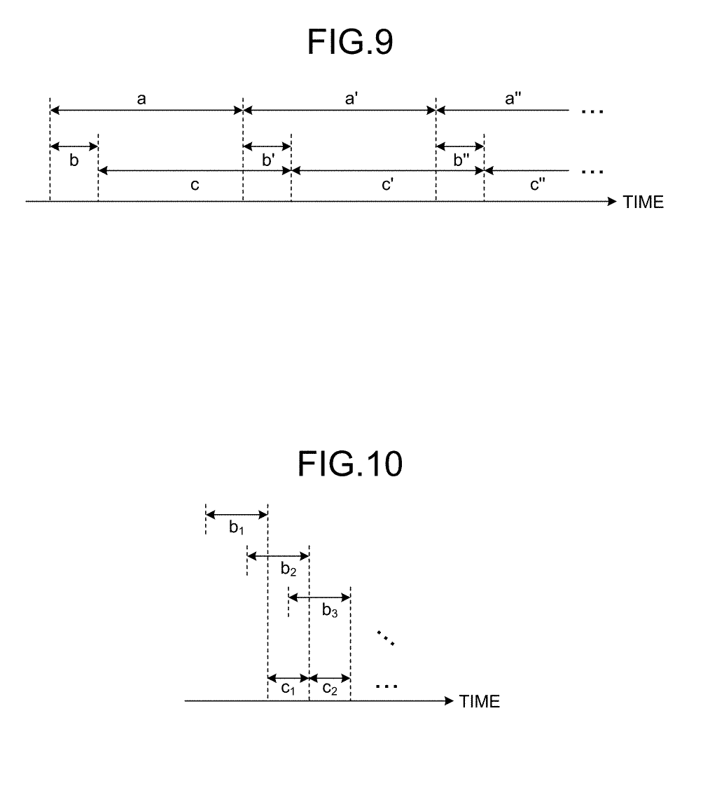

FIG. 9 is a schematic diagram illustrating an example of calculation timing of a threshold according to a third embodiment. In the third embodiment, for example, as illustrated in FIG. 9, first, the threshold Cₜₕ is calculated by using the samples that are present in the beginning of a second period b in a first period a. The calculated threshold Cₜₕ is used for the clip process performed in a period c during which the threshold Cₜₕ is calculated in the beginning of a second period b′ in a subsequent first period a′. Then, the threshold Cₜₕ that is calculated by using the samples in the beginning of the second period b′ in the first period a′ is used for the clip process in the period c′ during which the threshold Cₜₕ is calculated in the beginning of a second period b″ in a subsequent first period a″.

Furthermore, in the third embodiment, the first period a and the second period b are arbitrarily set. For example, in an environment in which communication traffic sharply varies, the first period a may also be set shorter with respect to the second period b. Consequently, the threshold Cₜₕ can be updated as needed in accordance with the variation in the communication environment. In contrast, in an environment in which communication traffic does not vary so much, the first period a may also be set longer with respect to the second period b. Consequently, the frequency of updating the threshold Cₜₕ is reduced and the processing load of the distortion compensation device 10 is reduced.

Furthermore, for example, as illustrated in FIG. 10, the second period b may also be overlapped with another second period b. FIG. 10 is a schematic diagram illustrating another example of calculation timing of the threshold according to the third embodiment. For example, as illustrated in FIG. 10, the threshold Cₜₕ calculated in the second period b₁ is used for the clip process performed in the period c₁ during which the threshold Cₜₕ is calculated in a subsequent second period b₂. Similarly, the threshold Cₜₕ calculated in the second period b₂ is used for the clip process in the period c₂ during which the threshold Cₜₕ is calculated in a subsequent second period b₃.

### Effects of the Third Embodiment

As is clear from the description above, in the distortion compensation device 10 according to the embodiment, the threshold Cₜₕ calculated in the beginning of the second period in the first period is used for the clip process during which the threshold Cₜₕ is calculated in the beginning of the second period in the first period. Consequently, it is possible to more stably improve the quality of the signal transmitted from the distortion compensation device 10.

### [d] Fourth Embodiment

### Configuration of the Distortion Compensation Device 10

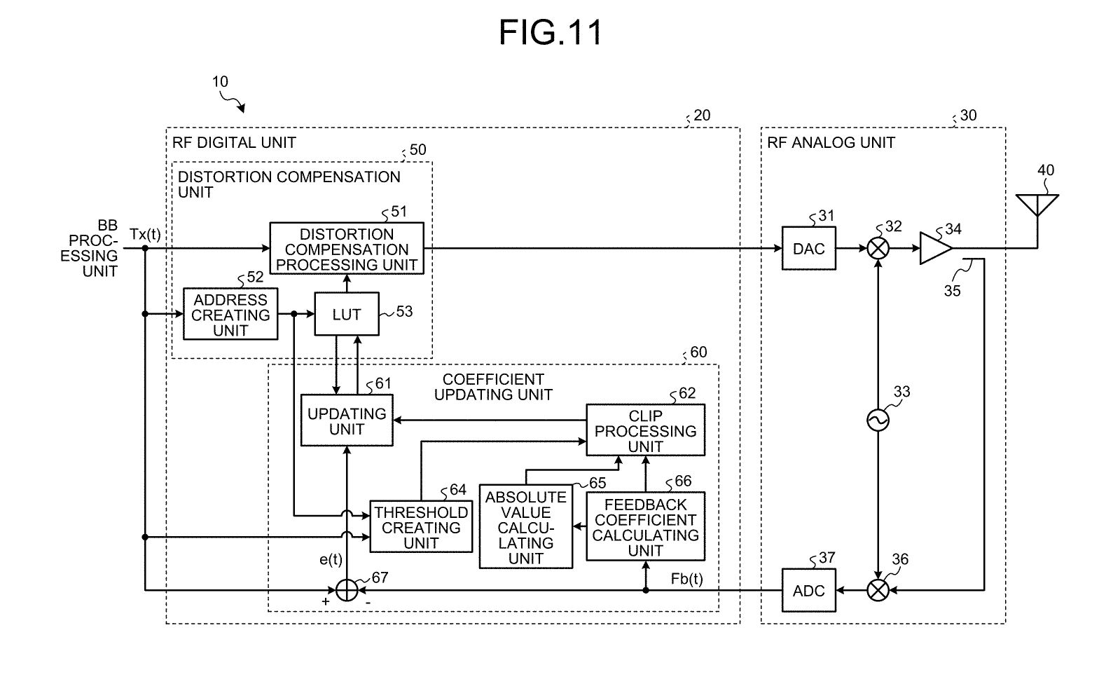

FIG. 11 is a block diagram illustrating an example of the distortion compensation device 10 according to a fourth embodiment. The distortion compensation device 10 according to the embodiment differs from the distortion compensation device 10 according to the first embodiment in that, if the value of the address of the transmission signal Tx(t) is equal to or less than the threshold Aₜₕ, the feedback coefficient Cⱼ is clipped by using the threshold Cₜₕ that is calculated based on the magnitude of the transmission signal Tx(t). Furthermore, the blocks illustrated in FIG. 11 having the same reference numerals as those illustrated in FIG. 1 have the same configuration as the blocks illustrated in FIG. 1 except for the following points described below; therefore, descriptions thereof will be omitted.

The threshold creating unit 64 determines whether the value of the address output from the address creating unit 52 is greater than the threshold Aₜₕ. If the value of the address output from the address creating unit 52 is greater than the threshold Aₜₕ, the threshold creating unit 64 outputs the maximum value to the clip processing unit 62 as the threshold Cₜₕ.

If the value of the address output from the address creating unit 52 is equal to or less than the threshold Aₜₕ, the threshold creating unit 64 creates the threshold Cₜₕ based on, for example, Equation (6) below. Then, the threshold creating unit 64 outputs the created threshold Cₜₕ to the clip processing unit 62.

$${C}_{th} = \frac{β}{α - \vert Tx ( t ) \vert} \qquad ( 6 )$$

In Equation (6) above, α and β are the predetermined constants.

The clip processing unit 62 receives, for each of the transmission signals Tx(t-j), the feedback coefficient Cⱼ from the feedback coefficient calculating unit 66 and receives the absolute value |Cⱼ| of the feedback coefficient Cⱼ from the absolute value calculating unit 65. Then, the clip processing unit 62 compares, for each of the transmission signals Tx(t-j), the absolute value |Cⱼ| received from the absolute value calculating unit 65 with the threshold Cₜₕ output from the threshold creating unit 64. If the value of the absolute value |Cⱼ| is equal to or less than the value of the threshold Cₜₕ, the clip processing unit 62 outputs the feedback coefficient Cⱼ received from the feedback coefficient calculating unit 66 to the updating unit 61.

In contrast, if the value of the absolute value |Cⱼ| is greater than the value of the threshold Cₜₕ, the clip processing unit 62 calculates the feedback coefficient Cⱼ′ based on Equation (5) described above. Then, the clip processing unit 62 outputs the feedback coefficient Cⱼ′ that has been subjected to the clip process to the updating unit 61.

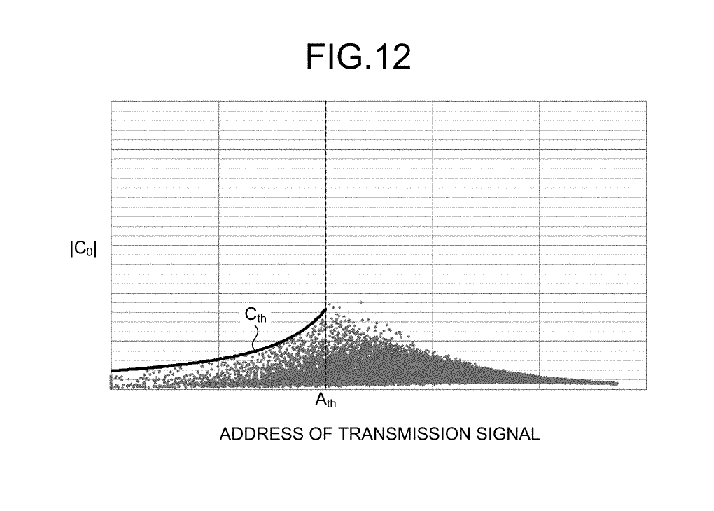

Consequently, the distribution of the feedback coefficients becomes the state illustrated in, for example, FIG. 12. FIG. 12 is a schematic diagram illustrating an example of distribution of the feedback coefficients according to the fourth embodiment. FIG. 12 illustrates an example of the distribution of the absolute values |C₀| calculated from the feedback signals Fb(t) that is associated with the transmission signals Tx(t) with the amount of delay of zero. Furthermore, the same distribution as that illustrated in FIG. 12 is also obtained regarding the absolute values |Cⱼ| calculated from the feedback signals Fb(t-j) associated with the transmission signals Tx(t-j) having another amount of delay. In the fourth embodiment, for example, as illustrated in FIG. 12, regarding the address having the value equal to or less than the threshold Aₜₕ, the value of the absolute value |Cⱼ| of the feedback coefficient Cⱼ is equal to or less than the threshold Cₜₕ and divergence of the feedback coefficient Cⱼ is suppressed. Consequently, the degradation of the accuracy of distortion compensation in the address having a small value is suppressed.

### Coefficient Updating Process

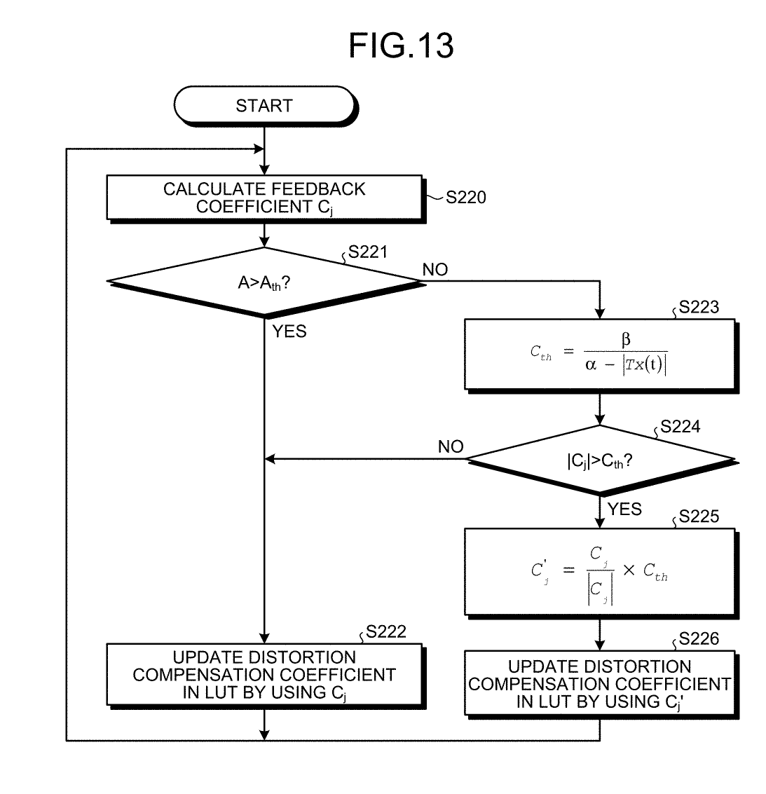

FIG. 13 is a flowchart illustrating an example of a coefficient updating process according to the fourth embodiment. The distortion compensation device 10 starts the coefficient updating process illustrated in FIG, 13 at a predetermined timing. For example, if the distortion compensation device 10 starts transmission of the DL signal in the mobile communication system, such as LTE, or the like, the distortion compensation device 10 starts the coefficient updating process illustrated in, for example, FIG. 13. Furthermore, in the following flowchart described, a description will be given of the transmission signal Tx(t-j) delayed by j samples and the feedback signal Fb(t-j); however, the same process is performed on each of the delay signals delayed by j represented by 0 to N.

First, the feedback coefficient calculating unit 66 calculates the feedback coefficient Cⱼ by performing the arithmetic operation indicated by Equation (3) described above by using the sampling data of the feedback signal Fb(t-j) associated with the sampling data of the transmission signal Tx(t-j) (Step S220). Then, the feedback coefficient calculating unit 66 outputs the calculated feedback coefficient Cⱼ to the clip processing unit 62.

Then, the threshold creating unit 64 determines whether the value of the address output from the address creating unit 52 is greater than the threshold Aₜₕ (Step S221). If the value of the address output from the address creating unit 52 is greater than the threshold Aₜₕ (Yes at Step S221), the threshold creating unit 64 outputs the maximum value to the clip processing unit 62 as the threshold Cₜₕ. Because the absolute value |Cⱼ| received from the absolute value calculating unit 65 is smaller than the threshold Cₜₕ output from the threshold creating unit 64, the clip processing unit 62 outputs the feedback coefficient Cⱼ received from the feedback coefficient calculating unit 66 to the updating unit 61.

The updating unit 61 calculates the updated distortion compensation coefficient hⱼ(p) by performing the arithmetic operation indicated by Equation (1) described above by using the feedback coefficient Cⱼ output from the clip processing unit 62. Then, the updating unit 61 updates the distortion compensation coefficient h′ⱼ(p) in the LUT 53 by using the calculated distortion compensation coefficient hⱼ(p) (Step S222). Then, the feedback coefficient calculating unit 66 again performs the process indicated at Step S220.

In contrast, if the value of the address output from the address creating unit 52 is equal to or less than the threshold Aₜₕ (No at Step S221), the threshold creating unit 64 creates the threshold Cₜₕ based on Equation (6) described above (Step S223). Then, the threshold creating unit 64 outputs the created threshold Cₜₕ to the clip processing unit 62. The clip processing unit 62 determines whether the absolute value |Cⱼ| received from the absolute value calculating unit 65 is greater than the threshold Cₜₕ output from the threshold creating unit 64 (Step S224). If the absolute value |Cⱼ| is equal to or less than the threshold Cₜₕ (No at Step S224), the clip processing unit 62 outputs the feedback coefficient Cⱼ received from the feedback coefficient calculating unit 66 to the updating unit 61. Then, the updating unit 61 performs the process indicated at Step S222.

In contrast, if the absolute value |Cⱼ| is greater than the threshold Cₜₕ (Yes at Step S224), the clip processing unit 62 calculates the feedback coefficient Cⱼ′ based on Equation (5) described above (Step S225). Then, the clip processing unit 62 outputs the feedback coefficient Cⱼ′ to the updating unit 61. The updating unit 61 calculates the updated distortion compensation coefficient hⱼ(p) by performing the arithmetic operation indicated by Equation (1) described above by using the feedback coefficient Cⱼ′ output form the clip processing unit 62. Then, the updating unit 61 updates the distortion compensation coefficient h′ⱼ(p) in the LUT 53 by using the calculated distortion compensation coefficient hⱼ(p) (Step S226). Then, the feedback coefficient calculating unit 66 again performs the process indicated at Step S220.

### Effects of the Fourth Embodiment

As is clear from the description above, in the distortion compensation device 10 according to the embodiment, if the value of the address of the transmission signal Tx(t) is equal to or less than the predetermined value, the feedback coefficient Cⱼ is clipped by using the threshold Cₜₕ that is calculated based on the magnitude of the transmission signal Tx(t). Consequently, it is possible to more stably improve the quality of the signal transmitted from the distortion compensation device 10.

### [e] Fifth Embodiment

### Configuration of the Distortion Compensation Device 10

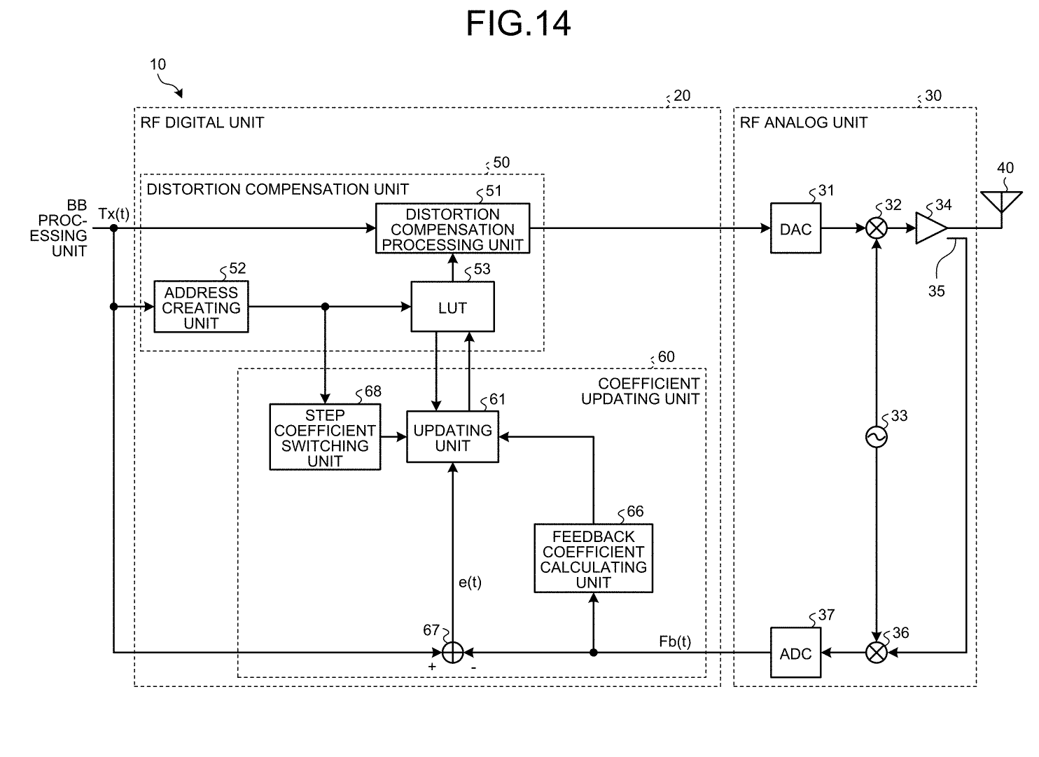

FIG. 14 is a block diagram illustrating an example of the distortion compensation device 10 according to a fifth embodiment. The distortion compensation device 10 according to the embodiment differs from the distortion compensation device 10 according to the first embodiment in that, instead of the process of clipping the feedback coefficient Cⱼ, the process of switching a step coefficient μ is performed in accordance with the value of the address of the transmission signal Tx(t-j). Furthermore, the blocks illustrated in FIG. 14 having the same reference numerals as those illustrated in FIG. 1 have the same configuration as the blocks illustrated in FIG. 1 except for the following points described below; therefore, descriptions thereof will be omitted.

The coefficient updating unit 60 according to the embodiment includes the updating unit 61, the feedback coefficient calculating unit 66, the subtracter 67, and a step coefficient switching unit 68. The feedback coefficient calculating unit 66 calculates the feedback coefficient Cⱼ for each of the transmission signals Tx(t-j) by performing the arithmetic operation based on Equation (3) described above by using the feedback signal Fb(t) output from the ADC 37. Then, the feedback coefficient calculating unit 66 outputs the calculated feedback coefficient Cⱼ to the updating unit 61. The subtracter 67 calculates the error e(t) by performing the arithmetic operation indicated by Equation (2) described above and outputs the calculated error e(t) to the updating unit 61.

The step coefficient switching unit 68 acquires, for each of the transmission signals Tx(t-j), the address created by the address creating unit 52. Then, the step coefficient switching unit 68 determines, for each of the transmission signals Tx(t-j), whether the value of the address is greater than the predetermined threshold Aₜₕ. Namely, the step coefficient switching unit 68 determines, for each of the transmission signals Tx(t-j) each having a different amount of delay, whether the amplitude of the transmission signal Tx(t-j) is greater than the predetermined value. Furthermore, because the threshold Aₜₕ is derived from the noise in the section from the amplifier to the ADC, the threshold Aₜₕ is set based on the measured value of the magnitude of the noise of this portion.

If the value of the address is greater than the predetermined threshold Aₜₕ, the step coefficient switching unit 68 outputs a step coefficient μ₀ that is a first value to the updating unit 61. In contrast, if the value of the address is equal to or less than the predetermined threshold Aₜₕ, the step coefficient switching unit 68 outputs, to the updating unit 61, a step coefficient μ₁ that is a second value smaller than the first value. Furthermore, the values of the step coefficients μ₀ and μ₁ are previously stored in a memory of the distortion compensation device 10 by an administrator of the distortion compensation device 10, or the like.

The updating unit 61 receives the feedback coefficient Cⱼ from the clip processing unit 62, receives the error e(t) from the subtracter 67, and receives the step coefficient μ₀ or μ₁ from the step coefficient switching unit 68. Furthermore, the updating unit 61 reads, from the LUT 53, the distortion, compensation coefficient h′ⱼ(p) that is before the update. Then, the updating unit 61 calculates the updated distortion compensation coefficient hⱼ(p) by performing the arithmetic operation indicated by Equation (1) described above. Then, the updating unit 61 updates the distortion compensation coefficient h′ⱼ(p) in the LUT 53 by using the calculated distortion compensation coefficient hⱼ(p).

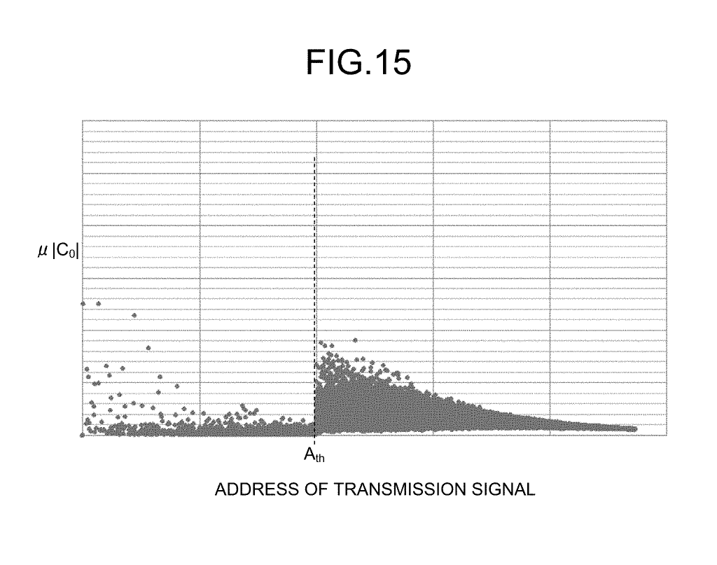

As described above, in the embodiment, in the process of updating the distortion compensation coefficient, regarding the transmission signal having the value of the address equal to or less than the threshold Aₜₕ, the step coefficient μ₁ having the value smaller than that of the step coefficient μ₀ that is applied to the transmission signal having the value of the address greater than the threshold is used. Consequently, for example, as illustrated in FIG. 15, in the transmission signal Tx(t) having the value of the address equal to or less than the threshold Aₜₕ, the value of the product of the absolute value |C₀| of the feedback coefficient C₀ and the step coefficient μ becomes small. FIG. 15 is a schematic diagram illustrating an example of distribution of the products of the absolute values |C₀| of the feedback coefficients C₀ and the step coefficient μ according to the fifth embodiment.

Consequently, the update amount of the distortion compensation coefficient with respect to the transmission signal Tx(t-j) having the value of the address equal to or less than the threshold Aₜₕ, i.e., the transmission signal Tx(t-j) having a small amplitude, is calculated as a small value. Consequently, in the update process of the distortion compensation coefficient performed on the transmission signal Tx(t-j) having the small amplitude, the influence of noise can be kept low. Consequently, the distortion compensation device 10 can improve the quality of the signal transmitted from the distortion compensation device 10.

### Coefficient Updating Process

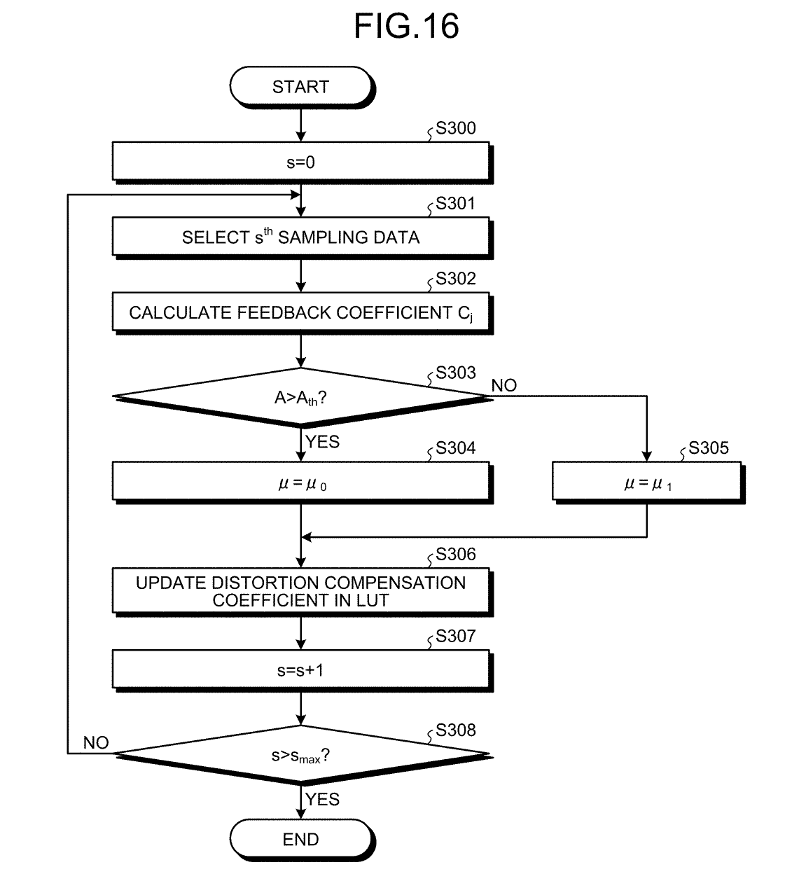

FIG. 16 is a flowchart illustrating an example of a coefficient updating process according to the fifth embodiment. The distortion compensation device 10 performs, at each predetermined timing, the coefficient updating process illustrated in FIG. 16. For example, if the distortion compensation device 10 transmits a DL signal in the mobile communication system, such as LTE, or the like, the distortion compensation device 10 performs, for each, for example, single frame, the coefficient updating process illustrated in FIG. 16. Furthermore, regarding the following flowchart, the transmission signal Tx(t-j) delayed by j samples and the feedback signal Fb(t-j) will be described, the same process is also performed on each of the delay signals delayed by j represented by 0 to N.

First, the feedback coefficient calculating unit 66 initializes the variable s that counts the sampling data of the transmission signal Tx(t-j) to zero (Step S300). Then, the feedback coefficient calculating unit 66 selects the sampling data of the feedback signal Fb(t-j) associated with the sampling data of the s^{th} transmission signal Tx(t-j) (Step S301). Then, the feedback coefficient calculating unit 66 calculates the feedback coefficient Cⱼ by performing the arithmetic operation indicated by Equation (3) described above by using the sampling data of the feedback signal Fb(t-j) selected at Step S301 (Step S302). Then, the feedback coefficient calculating unit 66 outputs the calculated feedback coefficient Cⱼ to the updating unit 61.

Then, the step coefficient switching unit 68 refers to the value of the address created by the address creating unit 52 and determines whether the value A of the subject address is greater than the predetermined threshold Aₜₕ (Step S303). If the value A of the address is greater than the predetermined threshold Aₜₕ (Yes at Step S303), the step coefficient switching unit 68 outputs, to the updating unit 61 as the step coefficient μ, the step coefficient μ₀ that is the first value (Step S304). In contrast, if the value A of the address is equal to or less than the predetermined threshold Aₜₕ (No at Step S303), the step coefficient switching unit 68 outputs, to the updating unit 61 as the step coefficient μ, the step coefficient μ₁ that is the second value and that is smaller than the step coefficient μ₀ that is the first value (Step S305).

Then, the updating unit 61 receives the feedback coefficient, Cⱼ from the feedback coefficient calculating unit 66, receives the error e(t) from the subtracter 67, and receives the step coefficient μ from the step coefficient switching unit 68. Furthermore, the updating unit 61 reads, from the LUT 53, the distortion compensation coefficient h′ⱼ(p) that is before the update. Then, the updating unit 61 calculates the updated distortion compensation coefficient hⱼ(p) by performing the arithmetic operation based on Equation (1) described above. Then, the updating unit 61 updates the distortion compensation coefficient h′ⱼ(p) in the LUT 53 by using the calculated distortion compensation coefficient hⱼ(p) (Step S306).

Then, the feedback coefficient calculating unit 66 increments the variable s by 1 (Step S307). Then, the feedback coefficient calculating unit 66 determines whether the value of the variable s is greater than the maximum value sₘₐₓ of the variable s (Step S308). In the embodiment, sₘₐₓ is, for example, 1000. If the value of the variable s is equal to or less than the value of sₘₐₓ (No at Step S308), the feedback coefficient calculating unit 66 again performs the process indicated at Step S301. In contrast, if the value of the variable s is greater than the value of sₘₐₓ (Yes at Step S308), the distortion compensation device 10 ends the process illustrated in the flowchart.

### Effect of the Fifth Embodiment

As is clear from the description above, the distortion compensation device 10 according to the embodiment includes the LUT 53, the feedback coefficient calculating unit 66, and the updating unit 61. The LUT 53 stores therein the distortion compensation coefficients. The feedback coefficient calculating unit 66 calculates the feedback coefficient based on the output signal from the power amplifier 34. The updating unit 61 updates the distortion compensation coefficients in the LUT 53 by using the error between the transmission signal that has not been subjected to distortion compensation and the output signal output from the power amplifier 34, by using the predetermined step coefficient, and by using the feedback coefficient output from the feedback coefficient calculating unit 66. Furthermore, when the updating unit 61 updates the distortion compensation coefficients associated with the transmission signal having the value equal to or less than the predetermined value, the updating unit 61 updates the distortion compensation coefficients by using the step coefficient μ that is the value smaller than that of the step coefficient μ₀ that is used to update the distortion compensation coefficients associated with the transmission signal having the value greater than the predetermined value. Consequently, the distortion compensation device 10 can improve the quality of the signal transmitted from the distortion compensation device 10.

### [f] Sixth Embodiment

### Configuration of the Distortion Compensation Device 10

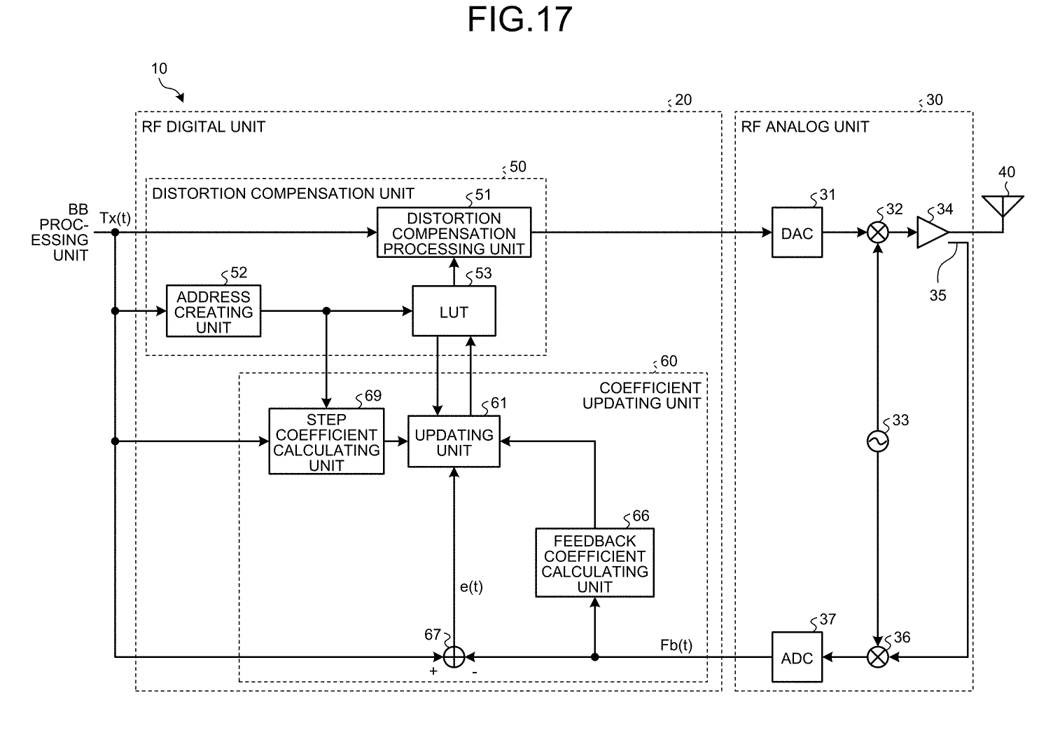

FIG. 17 is a block diagram illustrating an example of the distortion compensation device 10 according to a sixth embodiment. The distortion compensation device 10 according to the embodiment differs from the distortion compensation device 10 according to the fifth embodiment in that the distortion compensation coefficients are updated by using the step coefficient that is in accordance with the value of the address of the transmission signal. Furthermore, the blocks illustrated in FIG. 17 having the same reference numerals as those illustrated in FIG. 14 have the same configuration as the blocks illustrated in FIG. 14 except for the following points described below; therefore, descriptions thereof will be omitted

The coefficient updating unit 60 includes the updating unit 61, the feedback coefficient calculating unit 66, the subtracter 67, and a step coefficient calculating unit 69. The step coefficient calculating unit 69 acquires, for each of the transmission signals Tx(t-j) each having a different amount of delay, the address created by the address creating unit 52. Then, the step coefficient calculating unit 69 determines, for each of the transmission signals Tx(t-j), whether the value of the address is greater than the predetermined threshold Aₜₕ. Namely, the step coefficient calculating unit 69 determines, for each of the transmission signals Tx(t) each having a different amount of delay, whether the amplitude of the transmission signal Tx(t) is greater than the predetermined value,

If the value of the address is greater than the predetermined threshold Aₜₕ, the step coefficient calculating unit 69 outputs the step coefficient μ₀ to the updating unit 61. In contrast, if the value of the address is equal to or less than the predetermined threshold Aₜₕ, the step coefficient calculating unit 69 calculates the step coefficient μ₁ based on Equation (7) below and outputs the calculated step coefficient μ₁ to the updating unit 61.

$${μ}_{1} = \frac{β}{α - \vert Tx ( t ) \vert} \qquad ( 7 )$$

In Equation (7) above, α and β are a predetermined constant and are previously set in the step coefficient calculating unit 69 by an administrator of the distortion compensation device 10 or the like. Furthermore, regarding α and β, for example, in the transmission signal Tx(t) in which the value of the address is equal to or less than the threshold Aₜₕ, the value in which the value of the step coefficient μ₁ is smaller than the value of the step coefficient μ₀ is selected.

The updating unit 61 receives the feedback coefficient Cⱼ from the feedback coefficient calculating unit 66, receives the error e(t) from the subtracter 67, and receives the step coefficient μ from the step coefficient calculating unit 69. Furthermore, the updating unit 61 reads, from the LUT 53, the distortion compensation coefficient h′ⱼ(p) that is before the update. Then, the updating unit 61 calculates the updated distortion compensation coefficient hⱼ(p) based on Equation (1) described above and updates the distortion compensation coefficient h′ⱼ(p) in the LUT 53 by using the calculated distortion compensation coefficient hⱼ(p).

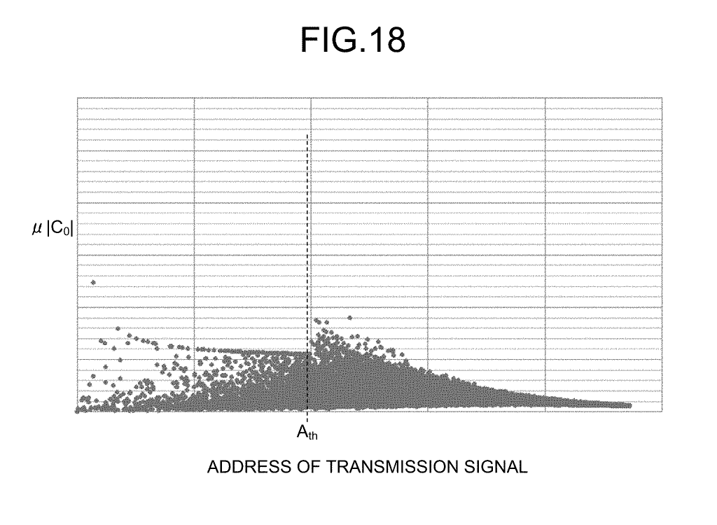

In this way, in the embodiment, in the process of updating the distortion compensation coefficient, regarding the transmission signal having the value of the address equal to or less than the threshold Aₜₕ, the step coefficient μ₁ calculated based on Equation (7) described above is used. Consequently, for example, as illustrated in FIG. 18, in the transmission signal Tx(t) having the address equal to or less than the threshold Aₜₕ, the value of the product of the absolute value |C₀| of the feedback coefficient C₀ and the step coefficient μ becomes small. FIG. 18 is a schematic diagram illustrating an example of distribution of the products of the absolute values |C₀| of feedback coefficients C₀ and step coefficient μ according to the sixth embodiment.

Consequently, an update amount of the distortion compensation coefficient with respect to the transmission signal Tx(t-j) having the value of the address equal to or less than the threshold Aₜₕ, i.e., the transmission signal Tx(t-j) with a small amplitude, is calculated as a small value. Thus, in the process of updating the distortion compensation coefficient with respect to the transmission signal Tx(t-j) with a small amplitude, the influence of noise can be kept low. Consequently, the distortion compensation device 10 can improve the quality of the signal transmitted from the distortion compensation device 10.

### Coefficient Updating Process

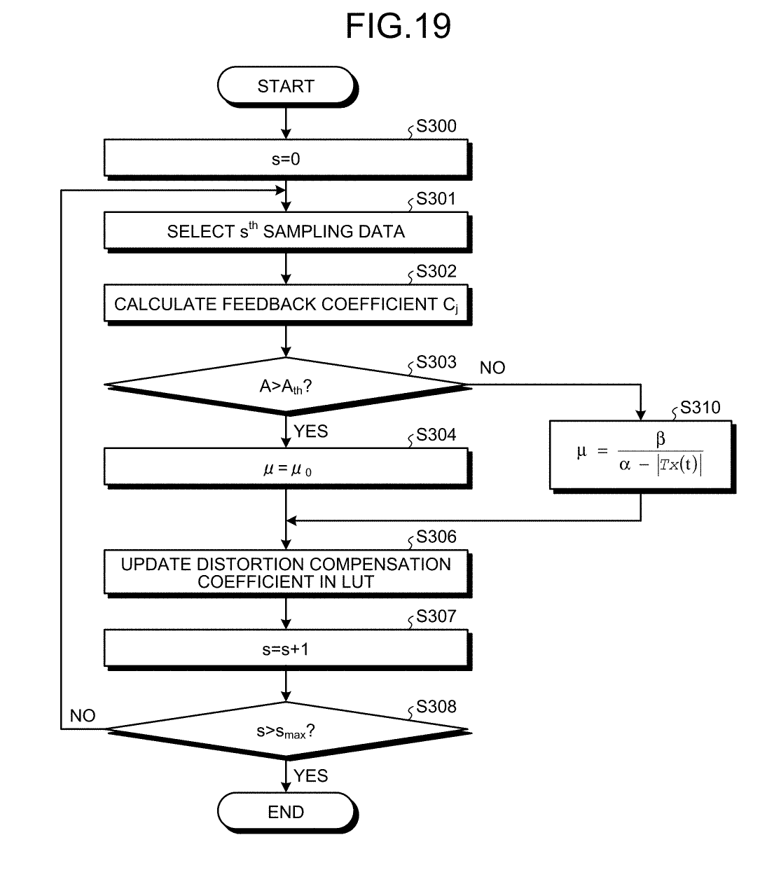

FIG. 19 is a flowchart illustrating an example of a coefficient updating process according to the sixth embodiment. The distortion compensation device 10 performs, at each predetermined timing, the coefficient updating process illustrated in FIG. 19. Furthermore, the processes illustrated in FIG. 19 having the same reference numerals as those illustrated in FIG. 16 have the same processes as those illustrated in FIG. 16 except for the following points described below; therefore, descriptions thereof will be omitted.

At Step S303, the step coefficient calculating unit 69 refers to the value of the address created by the address creating unit 52 determines whether the value A of the subject address is greater than the predetermined threshold Aₜₕ (Step S303). If the value A of the address is greater than the predetermined threshold Aₜₕ (Yes at Step S303), the step coefficient calculating unit 69 outputs the step coefficient μ₀ to the updating unit 61 as the step coefficient μ (Step S304). In contrast, if the value A of the address is equal to or less than the predetermined threshold Aₜₕ (No at Step S303), the step coefficient calculating unit 69 outputs, to the updating unit 61 as the step coefficient μ, the step coefficient μ₁ that is calculated based on Equation (7) described above (Step S310). Then, the updating unit 61 performs the process indicated at Step S306.

### Effect of the Sixth Embodiment

As is clear from the description above, in the distortion compensation device 10 according to the embodiment, when the updating unit 61 updates the distortion compensation coefficients associated with the transmission signal having the value equal to or less than the predetermined value, the updating unit 61 updates the distortion compensation coefficients by using the step coefficients calculated based on the magnitude of the transmission signal. Consequently, in the process of updating the distortion compensation coefficient associated with the transmission signal having a small amplitude, the influence of noise can be kept low and the quality of the signal transmitted from the distortion compensation device 10 can be improved.

### [g] Seventh Embodiment

### Configuration of the Distortion Compensation Device 10

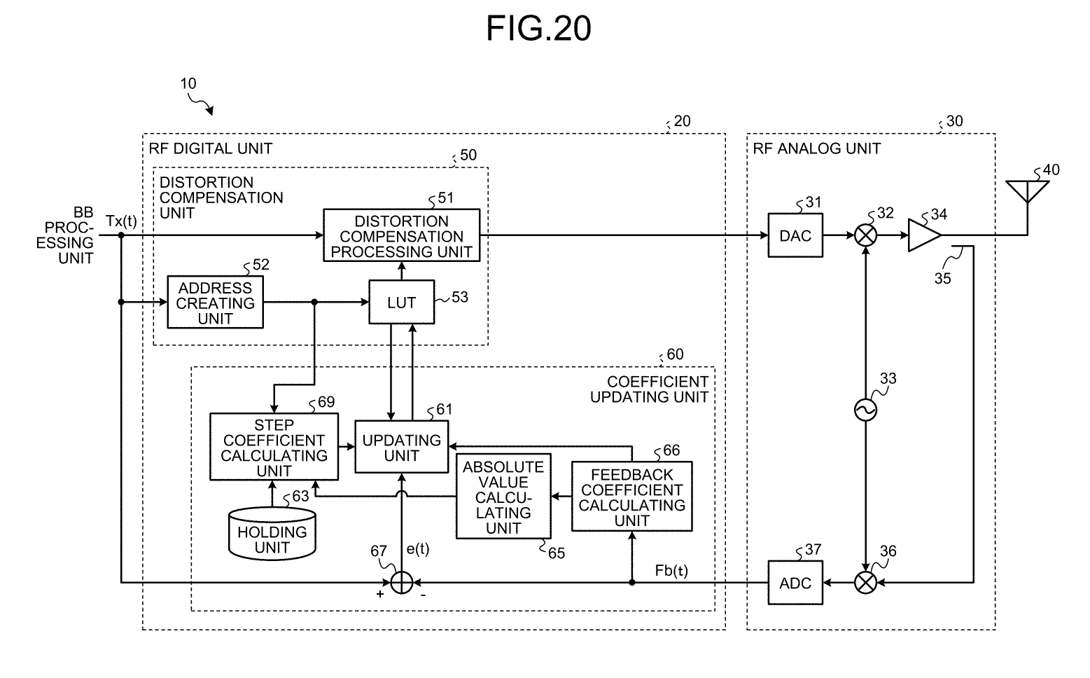

FIG. 20 is a block diagram illustrating an example of the distortion compensation device 10 according to a seventh embodiment. The distortion compensation device 10 according to the embodiment differs from the distortion compensation device 10 according to the sixth embodiment in that, if the value of the address of the transmission signal Tx(t) is equal to or less than the threshold Aₜₕ, the step coefficient μ is changed based on the ratio of the absolute value |Cⱼ| of the feedback coefficient Cⱼ to the threshold Cₜₕ. Furthermore, the blocks illustrated in FIG. 20 having the same reference numerals as those illustrated in FIG. 1 or 17 have the same configuration as the blocks illustrated in FIG. 1 or 17 except for the following points described below; therefore, descriptions thereof will be omitted

In the holding unit 63, the threshold Cₜₕ for each of the transmission signals Tx(t-j) is previously stored. The absolute value calculating unit 65 calculates, for each of the transmission signals Tx(t-j), the absolute value |Cⱼ| of the feedback coefficient Cⱼ output from the feedback coefficient calculating unit 66 and outputs the calculated absolute value |Cⱼ| to the step coefficient calculating unit 69.

The step coefficient calculating unit 69 acquires, for each of the transmission signals Tx(t-j) each having a different amount of delay, the address created by the address creating unit 52. Then, the step coefficient calculating unit 69 determines, for each of the transmission signals Tx(t-j), whether the value of the address is greater than the predetermined threshold Aₜₕ. If the value of the address is greater than the predetermined threshold Aₜₕ, the step coefficient calculating unit 69 outputs the step coefficient μ₀ to the updating unit 61.

In contrast, if the value of the address is equal to or less than the predetermined threshold Aₜₕ, the step coefficient calculating unit 69 calculates the step coefficient μ₁ based on, for example, Equation (8) below by using both the threshold Cₜₕ in the holding unit 63 and the absolute value |Cⱼ| output from the absolute value calculating unit 65. Then, the step coefficient calculating unit 63 outputs the calculated step coefficient μ₁ to the updating unit 61.

$${μ}_{1} = {μ}_{0} \frac{{C}_{th}}{\vert {C}_{j} \vert} \qquad ( 8 )$$

### Effect of the Seventh Embodiment

As is clear from the description above, in the distortion compensation device 10 according to the embodiment, if the value of the address of the transmission signal Tx(t) is equal to or less than the threshold Aₜₕ, the step coefficient calculating unit 69 changes the step coefficient μ based on the ratio of the absolute value |Cⱼ| of the feedback coefficient Cⱼ to the threshold Cₜₕ. Consequently, in the process of updating the distortion compensation coefficient with respect to the transmission signal having a small amplitude, the influence of noise can be kept low and the quality of the signal transmitted from the distortion compensation device 10 can be improved.

### Eighth Embodiment

### Configuration of the Distortion Compensation Device 10

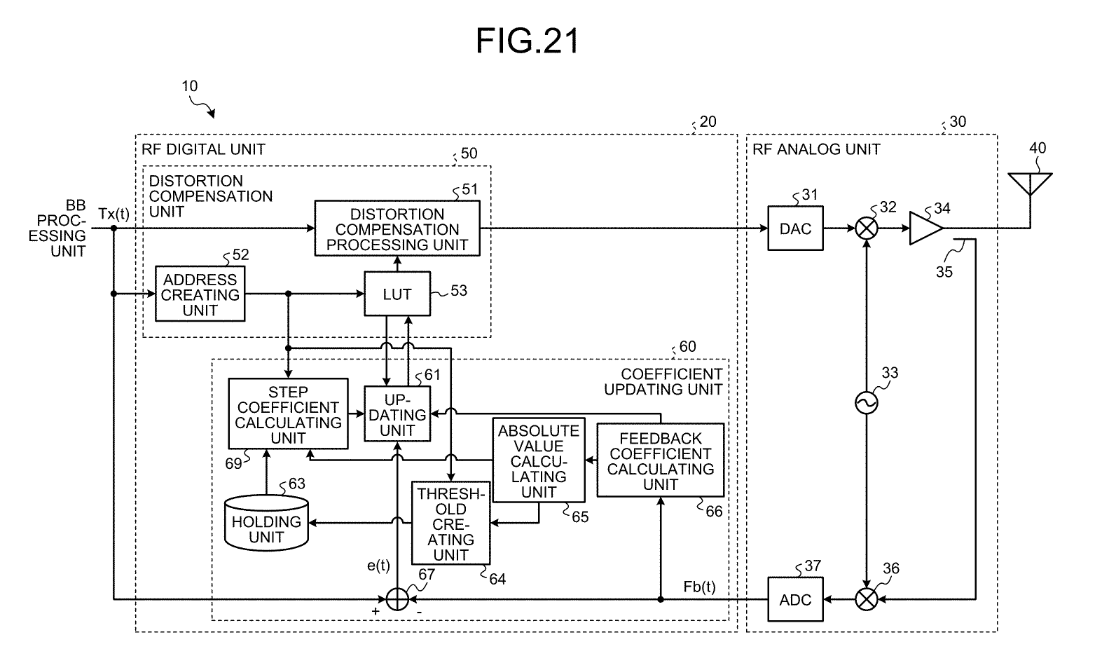

FIG. 21 is a block diagram illustrating an example of the distortion compensation device 10 according to an eighth embodiment. The eighth embodiment is a combination of the first embodiment and the seventh embodiment. Namely, the distortion compensation device 10 according to the embodiment specifies, as the threshold Cₜₕ, the maximum value of the absolute value |Cⱼ| of the feedback coefficient Cⱼ associated with the address having the value greater than the threshold Aₜₕ. Then, if the value of the address of the transmission signal Tx(t) is equal to or less than the threshold Aₜₕ, the distortion compensation device 10 according to the embodiment changes the step coefficient μ based on the ratio of the absolute value |Cⱼ| of the feedback coefficient Cⱼ to the threshold Cₜₕ. Furthermore, the blocks illustrated in FIG. 21 having the same reference numerals as those illustrated in FIG. 1 or 17 have the same configuration as the blocks illustrated in FIG. 1 or 17 except for the following points described below; therefore, descriptions thereof will be omitted.

The absolute value calculating unit 65 calculates, for each of the transmission signals Tx(t-j), the absolute value |Cⱼ| of the feedback coefficient Cⱼ output from the feedback coefficient calculating unit 66 and then outputs the calculated absolute value |Cⱼ| to both the threshold creating unit 64 and the step coefficient calculating unit 69. The threshold creating unit 64 creates, for each predetermined period, the threshold Cₜₕ by using the predetermined number of top samples included in the predetermined period related to the feedback coefficient Cⱼ associated with the transmission signal Tx(t-j). Specifically, the threshold creating unit 64 creates, as the threshold Cₜₕ, the maximum value from among the absolute values |Cⱼ| of the feedback coefficients Cⱼ associated with the address having the value greater than the threshold Aₜₕ. Then, the threshold creating unit 64 stores the created threshold Cₜₕ in the holding unit 63. The holding unit 63 stores therein the threshold Cₜₕ created for each of the transmission signals Tx(t-j) by the threshold creating unit 64.

The step coefficient calculating unit 69 acquires, for each of the transmission signals Tx(t-j) each having a different amount of delay, the address created by the address creating unit 52 and determines whether the value of the address is greater than the predetermined threshold Aₜₕ. If the value of the address is greater than the predetermined threshold Aₜₕ, the step coefficient calculating unit 69 outputs the step coefficient μ₀ to the updating unit 61.

In contrast, if the value of the address is equal to or less than the predetermined threshold Aₜₕ, the step coefficient calculating unit 69 calculates the step coefficient μ₁ based on, for example, Equation (8) described above by using both the threshold Cₜₕ in the holding unit 63 and the absolute value |Cⱼ| output from the absolute value calculating unit 65. Then, the step coefficient calculating unit 69 outputs the calculated step coefficient μ₁ to the updating unit 61.

Furthermore, similarly to the second embodiment described above, the threshold creating unit 64 may also create, as the threshold Cₜₕ for each of the transmission signals Tx(t-j), the value obtained by adding the predetermined offset C_{off} to the average value Cₐᵥₑ of the absolute values {Cⱼ} of the feedback coefficients Cⱼ associated with the transmission signals Tx(t-j).

### Effect of the Eighth Embodiment

As is clear from the description above, in the distortion compensation device 10 according to the embodiment, the threshold creating unit 64 creates, for each predetermined period, the threshold Cₜₕ by using the feedback coefficient Cⱼ. Furthermore, if the value of the address of the transmission signal Tx(t) is equal to or less than the threshold Aₜₕ, the step coefficient calculating unit 69 changes the step coefficient μ based on the ratio of the absolute value |Cⱼ| of the feedback coefficient Cⱼ to the threshold Cₜₕ. Consequently, in the process of updating the distortion compensation coefficient with respect to the transmission signal having a small amplitude, the influence of noise can be kept low and the quality of the signal transmitted from the distortion compensation device 10 can be improved.

### Hardware

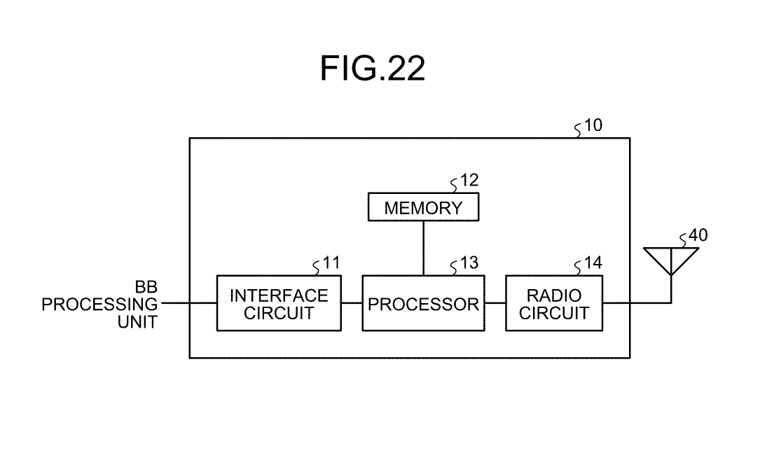

The distortion compensation device 10 according to the first to the eight embodiments can be implemented by, for example, the hardware illustrated in FIG. 22. FIG. 22 is a block diagram illustrating an example of hardware the distortion compensation device 10. The distortion compensation device 10 includes, for example, as illustrated in FIG. 22, an interface circuit 11, a memory 12, a processor 13, a radio circuit 14, and the antenna 40.

The interface circuit 11 is an interface for performing wired communication with the BB processing unit. The radio circuit 14 includes the power amplifier 34, or the like. The radio circuit 14 performs a process, such as up-conversion, or the like, on the signal output from the processor 13, amplifies the processed signal by using the power amplifier 34, and transmits the signal from the antenna 40. Furthermore, the radio circuit 14 performs a process, such as down-conversion, or the like, on a part of the signal amplified by the power amplifier 34 and feeds back the processed signal to the processor 13. In the radio circuit 14, for example, the DAC 31, the mixer 32, the oscillator 33, the power amplifier 34, the coupler 35, the mixer 36, the ADC 37, and the like are included.

The memory 12 stores therein various kinds of programs, data, and the like for implementing the function of, for example, the distortion compensation unit 50 and the coefficient updating unit 60. The processor 13 implements each of the functions of, for example, the distortion compensation unit 50 and the coefficient updating unit 60 by executing the programs read from the memory 12.

Furthermore, in the distortion compensation device 10 illustrated in FIG. 22 as an example, each of the single processor 13, the radio circuit 14, and the antenna 40 is provided; however, two or more of the processors 13, the radio circuits 14, and the antennas 40 may also be provided in the distortion compensation device 10.

Furthermore, the programs, the data, or the like in the memory 12 do not need to be stored in the memory 12 from the beginning. For example, each program, the data, or the like may also be stored in a portable recording medium, such as a memory card, or the like, inserted in the distortion compensation device 10 and the distortion compensation device 10 may also acquire each of the programs, the data, or the like from the portable recording medium and executes the programs. Furthermore, the distortion compensation device 10 may also acquire each of the programs from another computer, a server device, or the like that stores therein each program, the data, or the like via a wireless communication line, a public circuit, the Internet, a LAN, a WAN, or the like.

### Others

Furthermore, the technology disclosed in the present application is not limited to the embodiments described above and various modifications are possible as long as they do not depart from the spirit of the present application.

For example, in the first to the fourth and the eighth embodiments described above, the threshold Cₜₕ of the feedback coefficient Cⱼ is created for each of the transmission signals Tx(t-j); however, the disclosed technology is not limited to this. As another example, the threshold that is created from the feedback coefficient C₀ with respect to the transmission signal Tx(t) having the amount of delay of zero may also be used as the threshold Cₜₕ of the transmission signal Tx(t-j) having another delay signal. Consequently, it is possible to reduce the processing load applied to create the threshold Cₜₕ.

Furthermore, in each of the embodiments described above, a method of obtaining the distortion compensation coefficient for each magnitude of the amplitude or the power of the transmission signal and performing the distortion compensation (LUT method) by using the obtained distortion compensation coefficient has been described as an example; however, the disclosed technology is not limited to this. For example, instead of obtaining the distortion compensation coefficient for each magnitude of the amplitude or the power of the transmission signal, the disclosed technology can also be applied to a case of using a method (series method) of creating a distortion compensation signal based on a series expansion that uses the magnitude of the amplitude or the power of the transmission signal as an argument. In the series method, for example, the distortion compensation signal u(t) is created based on equation (9) below.

$$u ( t ) = {\sum }_{k = 1}^{k} {\sum }_{j = 0}^{Q} {\sum }_{i = 0}^{Q} {h}_{i , j , k} {\vert x ( t - i ) \vert}^{k - 1} x ( t - j ) \qquad ( 9 )$$

In Equation (9) above, h_{i, j, k} are examples of the distortion compensation coefficients and are updated by the coefficient updating unit 60 as needed.

Furthermore, in each of the embodiments described above, the feedback coefficient Cⱼ is calculated based on Equation (3) described above; however, the disclosed technology is not limited to this. The feedback coefficient Cⱼ may also be calculated based on, for example, Equation (10) or Equation (11) below.

$$\begin{matrix}{C}_{j} = \frac{{Fb}^{*} ( t - j )}{\frac{1}{N} {\sum }_{k = 0}^{N} {\vert Tx ( t - k ) \vert}^{2}} & ( 10 ) \\ {C}_{j} = \frac{{Tx}^{*} ( t - j )}{\frac{1}{N} {\sum }_{k = 0}^{N} {\vert Fb ( t - k ) \vert}^{2}} & ( 11 )\end{matrix}$$

Similarly, in each of the embodiments described above, the feedback coefficient C₀ is calculated based on Equation (4) described above; however, the disclosed technology is not limited to this. The feedback coefficient C₀ may also be calculated based on, for example, Equation (12) or Equation (13) below.

$${C}_{0} = \frac{{Fb}^{*} ( t )}{\frac{1}{N} {\sum }_{k = 0}^{N} {\vert Tx ( t - k ) \vert}^{2}} \qquad ( 12 )$$

$${C}_{0} = \frac{{Tx}^{*} ( t )}{\frac{1}{N} {\sum }_{k = 0}^{N} {\vert Fb ( t - k ) \vert}^{2}} \qquad ( 13 )$$

Furthermore, in each of the embodiments described above, the threshold Aₜₕ of the address is the fixed value; however, the disclosed technology is not limited to this. For example, one of the thresholds Aₜₕ between two thresholds Aₜₕ having different values may also be selected in accordance with the power of the distortion compensation signal that is input to the power amplifier 34. Specifically, if the value of the power of the distortion compensation signal is equal to or greater than the predetermined threshold Pₜₕ, the threshold Aₜₕ having a greater value between the two thresholds Aₜₕ is selected, whereas, if the value of the power of the distortion compensation signal is less than the threshold Pₜₕ, the threshold Aₜₕ having a smaller value is selected. The threshold Pₜₕ is set to, for example, the intermediate value between the maximum value of the power that can be input to the power amplifier 34 and the minimum value of the power of the transmission signal that is input to the power amplifier 34, such as a half of (the maximum value-the minimum value). In a case of heavy communication traffic, the power of the transmission signal input to the power amplifier 34 becomes large, whereas, in a case of low communication traffic, the power of the transmission signal that is input to the power amplifier 34 becomes small. Consequently, the distortion compensation device 10 can switch the threshold Aₜₕ in accordance with the variation in communication traffic.

According to an aspect of an embodiment, it is possible to improve the quality of transmission signals.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such superiority and inferiority of the invention. Although the embodiments of the present invention have been described in detail, it should be understood that the various changes, substitutions, and alterations could be made hereto without departing from the spirit and scope of the invention.

What is claimed is:

1. A distortion compensation device that compensates distortion generated in a power amplifier, the distortion compensation device comprising:
a distortion compensation unit that generates a distortion compensation signal by performing a predetermined arithmetic operation on a transmission signal by using a distortion compensation coefficient and that inputs the generated distortion compensation signal to the power amplifier;
a calculating unit that calculates a feedback coefficient based on an output signal output from the power amplifier;
a clip processing unit that outputs, when absolute value of the feedback coefficient calculated by the calculating unit is equal to or less than a threshold, the feedback coefficient calculated by the calculating unit and that outputs, when the absolute value of the feedback coefficient calculated by the calculating unit is greater than the threshold, the feedback coefficient of which absolute value is equal to or less than the threshold; and
an updating unit that updates the distortion compensation coefficient by using an error between the transmission signal and the output signal, a predetermined step coefficient, and the feedback coefficient output from the clip processing unit.

2. The distortion compensation device according to claim 1, wherein, when the absolute value of the feedback coefficient calculated by the calculating unit is greater than the threshold, the clip processing unit calculates the feedback coefficient of which absolute value is equal to or less than the threshold by multiplying the threshold by a value obtained by dividing the feedback coefficient by the absolute value of the feedback coefficient.

3. The distortion compensation device according to claim 1, further comprising a threshold calculating unit that calculates, for each of a predetermined number of samples of the transmission signal, the threshold based on the absolute value of the feedback coefficient calculated from the output signal associated with the transmission signal,

4. The distortion compensation device according to claim 3, wherein the threshold calculating unit calculates, as the threshold, a maximum value of the absolute value of the feedback coefficient calculated based on the output signal associated with the transmission signal having magnitude greater than a predetermined value among the predetermined number of samples of the transmission signal,

5. The distortion compensation device according to claim 3, wherein, regarding the predetermined number of samples of the transmission signal, the threshold calculating unit calculates, as the threshold, a value obtained by adding a predetermined offset to an average value of the absolute values of the feedback coefficients calculated based on the output signal associated with the transmission signal,

6. The distortion compensation device according to claim 1, further comprising a threshold calculating unit that calculates, for each of samples of the transmission signal, the threshold based on magnitude of the transmission signal.

7. The distortion compensation device according to claim 4, wherein the magnitude of the transmission signal is an amplitude or power of the transmission signal.

8. The distortion compensation device according to claim 1, wherein
the distortion compensation unit includes
a table that stores therein the distortion compensation coefficients, and
a multiplying unit that generates the distortion compensation signal by multiplying the distortion compensation coefficient by the transmission signal.

9. The distortion compensation device according to claim 1, wherein the distortion compensation unit generates the distortion compensation signal by performing a series expansion on the transmission signal by using the distortion compensation coefficients.

10. A distortion compensation device that compensates distortion generated in a power amplifier, the distortion compensation device comprising:
a distortion compensation unit that generates a distortion compensation signal by performing a predetermined arithmetic operation on a transmission signal by using a distortion compensation coefficient and that inputs the generated distortion compensation signal to the power amplifier;
a calculating unit that calculates a feedback coefficient based on an output signal output from the power amplifier; and
an updating unit that updates the distortion compensation coefficient by using an error between the transmission signal and the output signal, a predetermined step coefficient, and the feedback coefficient, wherein
when the updating unit updates the distortion compensation coefficient associated with the transmission signal having magnitude equal to or less than a predetermined value, the updating unit updates the distortion compensation coefficient by using the step coefficient having a value smaller than that of the step coefficient that is used to update the distortion compensation coefficient associated with the transmission signal having magnitude greater than the predetermined value.

11. The distortion compensation device according to claim 10, wherein, when the updating unit updates the distortion compensation coefficient associated with the transmission signal having the magnitude equal to or less than the predetermined value, the updating unit updates distortion compensation coefficient by using the step coefficient calculated based on magnitude of the transmission signal.

12. The distortion compensation device according to claim 10, further comprising a step coefficient calculating unit that calculates, for each of a predetermined number of samples of the transmission signal, the step coefficient based on ratio of the absolute value of the feedback coefficient calculated from the output signal associated with the transmission signal to a predetermined constant, wherein
when, the updating unit updates the distortion compensation coefficient associated with the transmission signal having the magnitude equal to or less than the predetermined value, the updating unit updates the distortion compensation coefficient by using the step coefficient calculated fey the step coefficient calculating unit.

13. The distortion compensation device according to claim 12, further comprising a threshold calculating unit that calculates, as the constant, a maximum value of the absolute value of the feedback coefficient calculated based on the output signal associated with the transmission signal having the magnitude greater than the predetermined value among the predetermined number of samples of the transmission signal.

14. The distortion compensation device according to claim 12, further comprising a threshold calculating unit that calculates, as the constant, regarding the predetermined number of samples of the transmission signal, a value obtained by adding a predetermined offset to an average value of the absolute values of the feedback coefficients calculated based on the output signal associated with the transmission signal.

15. The distortion compensation device according to claim 10, wherein the magnitude of the transmission signal is an amplitude or power of the transmission signal.

16. The distortion compensation device according to claim 10, wherein
the distortion compensation unit includes
a table that stores therein the distortion compensation coefficients, and
a multiplying unit that generates the distortion compensation signal by multiplying the distortion compensation coefficient by the transmission signal.

17. The distortion compensation device according to claim 20, wherein the distortion compensation unit generates the distortion compensation signal by performing a series expansion on the transmission signal by using the distortion compensation coefficients.

18. A coefficient update method performed by a distortion compensation device that compensates distortion generated in a power amplifier, the coefficient update method comprising:
generating a distortion compensation signal by performing a predetermined arithmetic operation on a transmission signal by using a distortion compensation coefficient and inputting the generated distortion compensation signal to the power amplifier;
calculating a feedback coefficient based on an output signal output from the power amplifier;
outputting the calculated feedback coefficient when absolute value of the calculated feedback coefficient is equal to or less than a threshold;
outputting the feedback coefficient of which absolute value is equal to or less than the threshold when the absolute value of the calculated feedback coefficient is greater than the threshold; and
updating the distortion compensation coefficient by using an error between the transmission signal and the output signal, a predetermined step coefficient, and the feedback coefficient.
